(19) United States
(12) Patent Application Publication
(10) Pub. No.: US 2010/0307559 A1
(43) Pub. Date: Dec. 9, 2010

(54) PHOTOELECTRIC CONVERSION DEVICE AND METHOD FOR MANUFACTURING THE SAME

(75) Inventors: Shunpei YAMAZAKI, Tokyo (JP); Yukie SUZUKI, Atsugi (JP); Kazuo NISHI, Fujisawa (JP); Yasuyuki ARAI, Atsugi (JP)

Correspondence Address: John F. Hayden;FISH & RICHARDSON P.C., 1425 K. Street, N. W. 11th Floor, Washington, DC, 20005, US

(73) Assignee: SEMICONDUCTOR ENERGY LABORATORY CO., LTD., Atsugi-shi (JP)

(21) Appl. No.: 12/793,329

(22) Filed: Jun. 3, 2010

(30) Foreign Application Priority Data
Jun. 5, 2009 (JP) 2009-136672

(51) Int. Cl. H01L 31/042; H01L 31/18

(52) U.S. Cl. 136/244; 438/66; 257/E31.052; 257/E31.11

(57) ABSTRACT

An object is to provide a photoelectric conversion device whose mechanical strength is increased without complicating a manufacturing process. The photoelectric conversion device includes a first cell having a photoelectric conversion function, a second cell having a photoelectric conversion function, and a structure body including a fibrous body which firmly attaches the first cell and the second cell. As a result, p-i-n junctions are bonded with the structure body in which the fibrous body is impregnated with an organic resin, which is a so-called prepreg. Thus, a photoelectric conversion device whose mechanical strength is increased can be realized while the manufacturing cost is reduced.

### TECHNICAL FIELD

The present invention relates to a photoelectric conversion device which can generate electric energy from light and a method for manufacturing the photoelectric conversion device.

### BACKGROUND ART

A solar cell is one kind of photoelectric conversion devices which, using a photovoltaic effect, directly convert received light into electric power and outputs the electric power. Unlike a conventional power generation system, a power generation system using the solar cell does not need energy conversion to thermal energy or kinetic energy in the process. Therefore, although if fuel is consumed when solar cells are produced or set, the solar cells have an advantage in that the amount of greenhouse gas typified by carbon dioxide or of emission gas containing a toxic substance per electric power generated is remarkably smaller than that of an energy source based on fossil fuel. In addition, the energy of light from the sun that reaches the earth for one hour corresponds to energy that is consumed by humans for one year. Materials that are necessary for production of the solar cells are basically abundant, and for example, there are almost infinite reserves of silicon. Solar photovoltaic power generation has a high possibility to meet the world's energy demand and is expected as alternative energy to fossil fuel whose reserves are finite.

A photoelectric conversion device using a semiconductor junction such as a p-n junction or a p-i-n junction can be classified into a single junction type which has one semiconductor junction and a multi junction type which has a plurality of semiconductor junctions. A multi junction solar cell in which a plurality of semiconductor junctions whose band gaps are different from each other are arranged so as to overlap with each other in a direction of travel of light can convert sunlight including light with a wide wavelength range from ultraviolet rays to infrared rays into electrical energy with higher conversion efficiency without waste.

As a method for manufacturing a photoelectric conversion device, for example, a method is proposed in which two substrates each having a p-i-n junction (or a p-n junction) face each other and are bonded to each other so that the substrates are located on the outer side, whereby a so-called mechanical stack structure is formed (e.g., see Patent Document 1). With such a structure being adopted, a photoelectric conversion device which has no limitation on a manufacturing process due to a stacked structure and which has high conversion efficiency can be realized.

### [Reference]

### [Patent Document 1] Japanese Published Patent Application No. 2004-111557

### DISCLOSURE OF INVENTION

However, since one p-i-n junction and another p-i-n junction are bonded to each other with an insulating resin in the photoelectric conversion device described in Patent Document 1, a problem is likely to occur to the bonding strength or the mechanical strength. In particular, in the case where a flexible substrate is used as a substrate over which a p-i-n junction is formed, it is very important to increase the mechanical strength.

In view of the above-described problem, it is an object of an embodiment of the present invention to provide a photoelectric conversion device whose mechanical strength is increased without complicating a manufacturing process.

An embodiment of the disclosed invention is a photoelectric conversion device including a first cell having a photoelectric conversion function, a second cell having a photoelectric conversion function, and a structure body including a fibrous body which is configured to firmly attach the first cell and the second cell.

An embodiment of the disclosed invention is a photoelectric conversion device including a first cell having a photoelectric conversion function which is formed over a first substrate, a second cell having a photoelectric conversion function which is formed over a second substrate, and a structure body including a fibrous body which is configured to firmly attach the first cell and the second cell.

According to an embodiment of the disclosed invention, in the photoelectric conversion device, the first cell may include a first photoelectric conversion layer interposed between a first conductive film and a second conductive film, and the second cell may include a second photoelectric conversion layer interposed between a third conductive film and a fourth conductive film.

According to an embodiment of the disclosed invention, in the photoelectric conversion device, the first photoelectric conversion layer may include a first p-type semiconductor layer and a first n-type semiconductor layer, and the second photoelectric conversion layer may include a second p-type semiconductor layer and a second n-type semiconductor layer.

According to an embodiment of the disclosed invention, in the photoelectric conversion device, a first i-type semiconductor layer may be formed between the first p-type semiconductor layer and the first n-type semiconductor layer, and a second i-type semiconductor layer may be formed between the second p-type semiconductor layer and the second n-type semiconductor layer.

According to an embodiment of the disclosed invention, in the photoelectric conversion device, each of the first substrate and the second substrate may be a flexible substrate.

According to an embodiment of the disclosed invention, in the photoelectric conversion device, the first cell and the second cell may face each other with the structure body therebetween so that the first substrate and the second substrate are positioned on the sides where the structure body is not provided.

According to an embodiment of the disclosed invention, in the photoelectric conversion device, the first cell or the second cell may include any of amorphous silicon, crystalline silicon, and single crystal silicon.

An embodiment of the disclosed invention is a method for manufacturing a photoelectric conversion device including the steps of forming a first cell having a photoelectric conversion function, forming a second cell having a photoelectric conversion function, and firmly attaching the first cell and the second cell with a structure body including a fibrous body.

An embodiment of the disclosed invention is a method for manufacturing a photoelectric conversion device including the steps of forming a first cell having a photoelectric conversion function over a first substrate, forming a second cell having a photoelectric conversion function over a second substrate, and firmly attaching the first cell and the second cell with a structure body including a fibrous body so that the first cell and the second cell are electrically connected.

According to an embodiment of the disclosed invention, in the method for manufacturing a photoelectric conversion device, a stacked-layer structure of a first conductive film, a first photoelectric conversion layer, and a second conductive film may be formed for the first cell, and a stacked-layer structure of a third conductive film, a second photoelectric conversion layer, and a fourth conductive film may be formed for the second cell.

According to an embodiment of the disclosed invention, in the method for manufacturing a photoelectric conversion device, the first photoelectric conversion layer is formed of a stacked layer of a first p-type semiconductor layer and a first n-type semiconductor layer, and the second photoelectric conversion layer is formed of a stacked layer of a second p-type semiconductor layer and a second n-type semiconductor layer.

According to an embodiment of the disclosed invention, in the method for manufacturing a photoelectric conversion device, a first i-type semiconductor layer may be formed between the first p-type semiconductor layer and the first n-type semiconductor layer, and a second i-type semiconductor layer may be formed between the second p-type semiconductor layer and the second n-type semiconductor layer.

According to an embodiment of the disclosed invention, in the method for manufacturing a photoelectric conversion device, the first cell and the second cell may be formed using a flexible first substrate and a flexible second substrate.

According to an embodiment of the disclosed invention, in the method for manufacturing a photoelectric conversion device, the first cell and the second cell may be bonded to face each other with a structure body therebetween so that the first substrate and the second substrate are positioned on the sides where the structure body is not provided.

According to an embodiment of the disclosed invention, in the method for manufacturing a photoelectric conversion device, the first cell or the second cell includes any of amorphous silicon, crystalline silicon, and single crystal silicon.

According to an embodiment of the disclosed invention, since one p-i-n junction and another p-i-n junction are bonded with a structure body in which a fibrous body is impregnated with an organic resin, which is a so-called prepreg, a photoelectric conversion device whose mechanical strength is increased can be realized while the manufacturing cost is controlled.

### BRIEF DESCRIPTION OF DRAWINGS

In the accompanying drawings:

FIG. 1 is a cross-sectional view of a photoelectric conversion device;

FIGS. 2A and 2B are cross-sectional views of photoelectric conversion devices;

FIGS. 3A and 3B are cross-sectional views of photoelectric conversion devices;

FIGS. 4A and 4B are cross-sectional views of photoelectric conversion device;

FIGS. 5A and 5B are top views of woven fabrics;

FIGS. 6A to 6E are cross-sectional views of a method for manufacturing a photoelectric conversion device;

FIGS. 7A to 7C are cross-sectional views of a method for manufacturing a photoelectric conversion device;

FIGS. 8A to 8E are cross-sectional views illustrating a method for manufacturing a photoelectric conversion device;

FIGS. 9A to 9G are cross-sectional views illustrating a method for manufacturing a photoelectric conversion device;

FIGS. 10A to 10C are views illustrating a processing method of a single crystal silicon wafer;

FIGS. 11A to 11C are cross-sectional views illustrating a method for manufacturing a photoelectric conversion device;

FIG. 12 is a cross-sectional view of a photoelectric conversion device;

FIG. 13 is a view illustrating a structure of an apparatus used for manufacture of a photoelectric conversion layer;

FIG. 14 is a view illustrating a structure of an apparatus used for manufacture of a photoelectric conversion layer;

FIGS. 15A and 15B are views illustrating a structure of a solar photovoltaic module;

FIG. 16 is a view illustrating a structure of a solar photovoltaic system;

FIGS. 17A and 17B are views illustrating a structure of a vehicle using a solar photovoltaic module;

FIG. 18 is a diagram illustrating one mode of an inverter;

FIG. 19 is a block diagram of a switching regulator;

FIG. 20 is a graph showing output voltage from a photoelectric conversion device;

FIG. 21 is a diagram illustrating an example of a photovoltaic system;

FIG. 22 is a view illustrating a peripheral portion of a photoelectric conversion module;

FIG. 23 is a view illustrating a peripheral portion of a photoelectric conversion module;

FIG. 24 is a graph showing the dependence of absorption coefficients of amorphous silicon (a-Si) and single crystal silicon (c-Si) on wavelengths;

FIG. 25 is a graph showing the dependence of quantum efficiency of a photoelectric conversion layer using amorphous silicon (a-Si) on wavelengths;

FIG. 26 is a graph showing the dependence of quantum efficiency of a photoelectric conversion layer using single crystal silicon (c-Si) on wavelengths; and

FIG. 27 is a graph showing the dependence of quantum efficiency of a structure in which photoelectric conversion layers are stacked on wavelengths.

### BEST MODE FOR CARRYING OUT THE INVENTION

Hereinafter, embodiments are described in detail using the drawings. Note that the present invention is not limited to the description of the embodiments below, and it is easily understood by those skilled in the art that the modes and details can be modified in various ways without departing from the spirit of the present invention. Therefore, the present invention should not be construed as being limited to the description of embodiments below.

Note that one or more solar cells (cells) are connected to a terminal that is used to extract electric power outside in order to obtain a solar cell module or a solar cell panel. The solar cell module may be reinforced with a protective material such as a resin, tempered glass, or a metal frame in order to protect the cell from moisture, dirt, ultraviolet rays, physical stress, or the like. In addition, a plurality of solar cell modules which are connected in series in order to obtain desired electric power correspond to a solar cell string. Further, a plurality of solar cell strings which are arranged in parallel correspond to a solar cell array. The photoelectric conversion device of the present invention includes, in its category, the cell, the solar cell module, the solar cell string, and the solar cell array. The photoelectric conversion layer refers to a layer including a semiconductor layer which is used to obtain photoelectromotive force through light irradiation. That is, the photoelectric conversion layer refers to a semiconductor layer in which a semiconductor junction typified by a p-n junction, a p-i-n junction, or the like is formed.

Note that the size, the thickness of layers, or regions in each of the structures illustrated in drawings or the like in embodiments is exaggerated for simplicity in some cases. Therefore, embodiments of the present invention are not limited to such scales.

In this specification, ordinal numbers such as “first”, “second”, and “third” are used in order to avoid confusion among components, and the terms do not limit the components numerically. In addition, the ordinal numbers in this specification do not denote particular names which specify the present invention.

### Embodiment 1

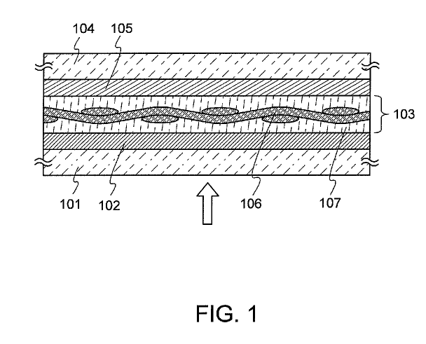

A photoelectric conversion device according to one embodiment of the present invention includes at least two cells. The cells each have a single-layer structure or a stacked-layer structure of a photoelectric conversion layer which is the minimum unit having a photoelectric conversion function. Further, the photoelectric conversion device has at least one structure body that is formed by impregnating a fiber body with a resin, which is interposed between the two cells. The structure of the photoelectric conversion device according to one embodiment of the present invention will be described with reference to FIG. 1.

A photoelectric conversion device illustrated in FIG. 1 includes a cell 102 (also referred to as a first cell) held by a substrate 101 (also referred to as a first substrate), a structure body 103, and a cell 105 (also referred to as a second cell) held by a substrate 104 (also referred to as a second substrate). The structure body 103 is interposed between the cell 102 and the cell 105. The cell 102 and the cell 105 each have one or more photoelectric conversion layers which are stacked. The photoelectric conversion layer included in the cell 102, the structure body 103, and the photoelectric conversion layer included in the cell 105 are arranged in that order so as to overlap with each other in a direction of travel of light as indicated by an arrow. The cell 102 and the cell 105 are electrically insulated by the structure body 103 in a region where the cell 102, the structure body 103, and the cell 105 are overlapped. A p-n or p-i-n junction of the cell 102 and a p-n or p-i-n junction of the cell 105 are electrically connected in parallel in a region where the cell 102, the structure body 103, and the cell 105 are not overlapped.

The photoelectric conversion layer has one semiconductor junction. Note that the photoelectric conversion layer which can be used in the photoelectric conversion device of the present invention disclosed herein is not always needed to have a semiconductor junction. For example, a dye-sensitized photoelectric conversion layer which obtains photoelectromotive force using an organic dye that absorbs light may also be used.

The structure body 103 can be formed in such a manner that a fibrous body 106 formed from an organic compound or an inorganic compound is impregnated with an organic resin 107. The structure body 103 is interposed between the cell 102 which is held by the substrate 101 and the cell 105 held by the substrate 104 and subjected to thermocompression bonding, whereby the cell 102, the structure body 103, and the cell 105 can be firmly attached to each other. A layer for firmly attaching the cell 102 and the structure body 103 may be provided between the cell 102 and the structure body 103, or a layer for firmly attaching the structure body 103 and the cell 105 may be provided between the structure body 103 and the cell 105. The cell 102, the structure body 103, and the cell 105 may be firmly attached to each other in such a manner that after a fibrous body 106 is disposed so as to overlap with either one of the cell 102 or the cell 105, the fibrous body 106 is impregnated with the organic resin 107 to form the structure body 103, and then the structure body 103 is disposed so as to overlap with the other. Note that the substrate 101 and the substrate 104 are preferably arranged to face each other with the structure body 103 therebetween so that the substrate 101 and the substrate 104 are located on the outer side (the side opposite to the side where the structure body 103 is provided), in which case the cell 102 and the cell 105 are protected by the substrate 101 and the substrate 104.

As the fibrous body 106, a woven fabric or a nonwoven fabric which uses high-strength fiber of an organic compound or an inorganic compound can be used. The high-strength fiber is specifically a fiber with a high tensile modulus of elasticity or a high Young's modulus. The use of the high-strength fiber as the fibrous body 106 allows pressure to be spread throughout the fibrous body 106 even when the pressure is locally applied to the cell; therefore, the cell can be prevented from being partly stretched. That is, destruction of a wiring, the cell, or the like due to the stretching of part of the cell can be prevented. Further, as the organic resin 107, a thermoplastic resin or a thermosetting resin can be used.

Note that the case where the structure body 103 includes the single-layer fibrous body 106 is illustrated as an example in FIG. 1; however, the photoelectric conversion device of the disclosed invention is not limited to this structure. In the structure body 103, two or more layers of fiber bodies may be stacked. In particular, when three or more layers of fiber bodies are used in the structure body 103, the reliability of the photoelectric conversion device in terms of resistance to external force, especially, pressing force can be improved in the case where a flexible substrate is used as each of the substrate 101 and the substrate 104. Note that the effect of the structure is confirmed from the experimental result.

The thickness of the structure body 103 is preferably 10 μm to 100 μm inclusive, more preferably 10 μm to 30 μm inclusive. In the case where a flexible substrate is used as each of the substrate 101 and the substrate 104, the use of the structure body 103 with the above thickness makes it possible to manufacture a photoelectric conversion device which is thin and can be bent.

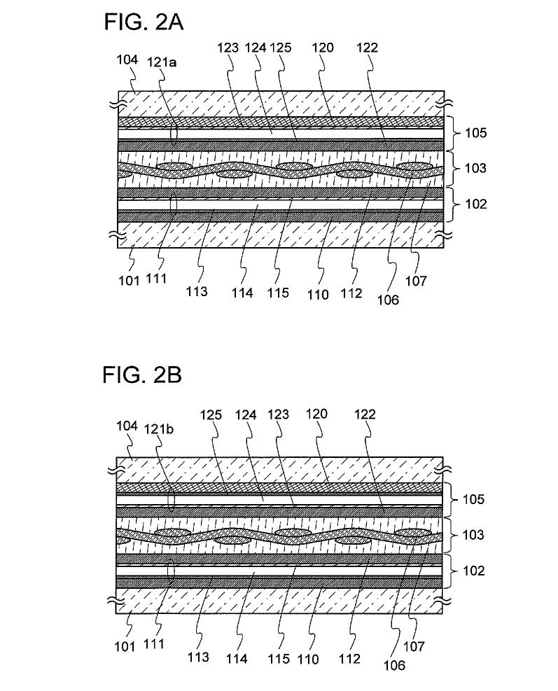

Next, the cell 102 held by the substrate 101 and the cell 105 held by the substrate 104 will be described. In the case where the photoelectric conversion layers included in the cell 102 and the cell 105 each have a semiconductor junction, the semiconductor junction may be a p-i-n junction or a p-n junction. In each of FIGS. 2A and 2B, a cross-sectional view of a photoelectric conversion device in which the cell 102 and the cell 105 each have a p-i-n junction is illustrated as an example.

In the photoelectric conversion device illustrated in FIG. 2A, the cell 102 (the first cell) includes a conductive film 110 (also referred to as a first conductive film) functioning as an electrode, a photoelectric conversion layer 111 (also referred to as a first photoelectric conversion layer), and a conductive film 112 (also referred to as a second conductive film) functioning as an electrode. The conductive film 110, the photoelectric conversion layer 111, and the conductive film 112 are stacked in that order from the substrate 101 side. The photoelectric conversion layer 111 includes a p layer 113 (also referred to as a first p-type semiconductor layer), an i layer 114 (also referred to as a first i-type semiconductor layer), and an n layer 115 (also referred to as a first n-type semiconductor layer). The p layer 113, the i layer 114, and the n layer 115 are stacked in that order from the conductive film 110 side, whereby a p-i-n junction is formed. In addition, the cell 105 (the second cell) includes a conductive film 120 (also referred to as a third conductive film) functioning as an electrode, a photoelectric conversion layer 121a (also referred to as a second photoelectric conversion layer), and a conductive film 122 (also referred to as a fourth conductive layer) functioning as an electrode. The conductive film 120, the photoelectric conversion layer 121a, and the conductive film 122 are stacked in that order from the substrate 104 side. The photoelectric conversion layer 121a includes a p layer 125 (also referred to as a second p-type semiconductor layer), an i layer 124 (also referred to as a second i-type semiconductor layer), and an n layer 123 (also referred to as a second n-type semiconductor layer). The n layer 123, the i layer 124, and the p layer 125 are stacked in that order from the conductive film 120 side, whereby a p-i-n junction is formed.

Note that the p layer refers to a p-type semiconductor layer, the i layer refers to an i-type semiconductor layer, and the n layer refers to an n-type semiconductor layer.

Thus, when the attention is focused on only the photoelectric conversion layer 111 and the photoelectric conversion layer 121a of the photoelectric conversion device illustrated in FIG. 2A, the p layer 113, the i layer 114, the n layer 115, the p layer 125, the i layer 124, and the n layer 123 are stacked in that order from the substrate 101 side. Thus, a photoelectric conversion device in which a p-i-n junction of the cell 102 and a p-i-n junction of the cell 105 are electrically connected in parallel can be manufactured. The fibrous body 106 is included in the structure body 103, which allows a photoelectric conversion device whose mechanical strength is increased to be realized.

On the other hand, in the photoelectric conversion device illustrated in FIG. 2B, the p layer 125, the i layer 124, and the n layer 123 included in a photoelectric conversion layer 121b are stacked in reverse order to that in the photoelectric conversion layer 121a illustrated in FIG. 2A.

Specifically, in the photoelectric conversion device illustrated in FIG. 2B, the cell 102 includes the conductive film 110 functioning as an electrode, the photoelectric conversion layer 111, and the conductive film 112 functioning as an electrode. The conductive film 110, the photoelectric conversion layer 111, and the conductive film 112 are stacked in that order from the substrate 101 side. The photoelectric conversion layer 111 includes the p layer 113, the i layer 114, and the n layer 115. The p layer 113, the i layer 114, and the n layer 115 are stacked in that order from the conductive film 110 side, whereby a p-i-n junction is formed. In addition, the cell 105 includes the conductive film 120 functioning as an electrode, the photoelectric conversion layer 121b, and the conductive film 122 functioning as an electrode. The conductive film 120, the photoelectric conversion layer 121b, and the conductive film 122 are stacked in that order from the substrate 104 side. The photoelectric conversion layer 121b includes the p layer 125, the i layer 124, and the n layer 123. The p layer 125, the i layer 124, and the n layer 123 are stacked in that order from the conductive film 120 side, whereby a p-i-n junction is formed.

Thus, when the attention is focused on only the photoelectric conversion layer 111 and the photoelectric conversion layer 121b of the photoelectric conversion device illustrated in FIG. 2B, the p layer 113, the i layer 114, the n layer 115, the n layer 123, the i layer 124, and the p layer 125 are stacked in that order from the substrate 101 side. Thus, a photoelectric conversion device in which a p-i-n junction of the cell 102 and a p-i-n junction of the cell 105 are electrically connected in parallel can be manufactured. The fibrous body 106 is included in the structure body 103, which allows a photoelectric conversion device whose mechanical strength is increased to be realized.

Note that in FIG. 2B, the p layer 113 is closer to the substrate 101 than the n layer 115, and the p layer 125 is closer to the substrate 104 than the n layer 123; however, the disclosed invention is not limited to this structure. In the photoelectric conversion device according to one embodiment of the disclosed invention, the n layer 115 may be closer to the substrate 101 than the p layer 113, and the n layer 123 may be closer to the substrate 104 than the p layer 125.

Note that in the photoelectric conversion devices illustrated in FIGS. 2A and 2B, light may enter from the substrate 101 side or may enter from the substrate 104 side. Note that it is preferable that the p layer 113 be closer to the light incident side than the n layer 115. The life of a hole as a carrier is as short as approximately half of the life of an electron as a carrier. When light enters the photoelectric conversion layer 111 having the p-i-n junction, a large number of electrons and holes are formed in the i layer 114, and the electrons move to the n layer 115 side and holes move to the p layer 113 side, so that electromotive force can be obtained. When light enters from the p layer 113 side, a large number of electrons and holes are formed in a region in the i layer 114, which is closer to the p layer 113 than to the n layer 115. Accordingly, a distance to the p layer 113 to which the holes having short life move can be shortened; as a result, high electromotive force can be obtained. For the same reason, the p layer 125 is preferably closer to the light incident side than the n layer 123.

The case where the cell 102 and the cell 105 each include one unit cell, that is, one photoelectric conversion layer in each of the photoelectric conversion devices illustrated in FIGS. 2A and 2B is described as an example; however, the disclosed invention is not limited to this structure. Each of the cell 102 and the cell 105 may have a plurality of photoelectric conversion layers or a single photoelectric conversion layer. Note that in the case where the cell 102 has a plurality of photoelectric conversion layers, the plurality of photoelectric conversion layers are sequentially stacked from the substrate 101 side, and the p layer, the i layer, and the n layer in each of the photoelectric conversion layers included in the cell 102 provided between the substrate 101 and the structure body 103 are stacked in that order so as to be electrically connected in series.

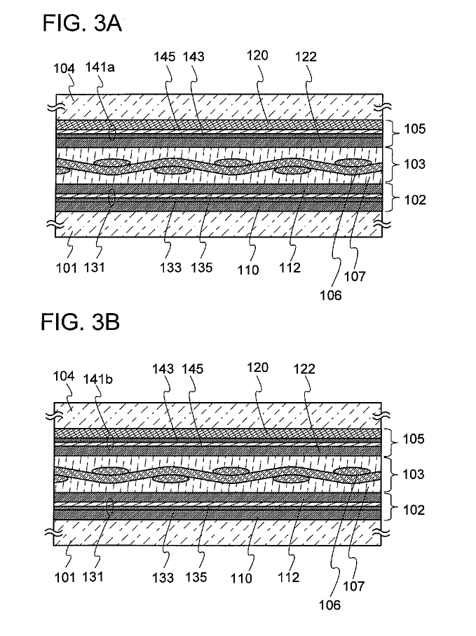

Next, each of FIGS. 3A and 3B is an example of a cross-sectional view of a photoelectric conversion device in which the cell 102 and the cell 105 each have a p-n junction.

In the photoelectric conversion device illustrated in FIG. 3A, the cell 102 includes the conductive film 110 functioning as an electrode, a photoelectric conversion layer 131 (also referred to as a first photoelectric conversion layer), and the conductive film 112 functioning as an electrode. The conductive film 110, the photoelectric conversion layer 131, and the conductive film 112 are stacked in that order from the substrate 101 side. The photoelectric conversion layer 131 includes a p layer 133 (also referred to as a first p-type semiconductor layer) and an n layer 135 (also referred to as a first n-type semiconductor layer). The p layer 133 and the n layer 135 are stacked in that order from the conductive film 110 side, whereby a p-n junction is formed. In addition, the cell 105 includes the conductive film 120 functioning as an electrode, a photoelectric conversion layer 141a (also referred to as a second photoelectric conversion layer), and the conductive film 122 functioning as an electrode. The conductive film 120, the photoelectric conversion layer 141a, and the conductive film 122 are stacked in the order from the substrate 104 side. The photoelectric conversion layer 141a includes a p layer 143 (also referred to as a second p-type semiconductor layer) and an n layer 145 (also referred to as a second n-type semiconductor layer). The n layer 145 and the p layer 143 are stacked in that order from the conductive film 120 side, whereby a p-n junction is formed.

Thus, when the attention is focused on only the photoelectric conversion layer 131 and the photoelectric conversion layer 141a of the photoelectric conversion device illustrated in FIG. 3A, the p layer 133, the n layer 135, the p layer 143, and the n layer 145 are stacked in that order from the substrate 101 side. Thus, a photoelectric conversion device in which a p-n junction of the cell 102 and a p-n junction of the cell 105 are electrically connected in parallel can be manufactured. The fibrous body 106 is included in the structure body 103, which allows a photoelectric conversion device whose mechanical strength is increased to be realized.

On the other hand, in the photoelectric conversion device illustrated in FIG. 3B, the p layer 143 and the n layer 145 included in a photoelectric conversion layer 141b are stacked in reverse order to that in the photoelectric conversion layer 141a illustrated in FIG. 3A.

Specifically, in the photoelectric conversion device illustrated in FIG. 3B, the cell 102 includes the conductive film 110 functioning as an electrode, the photoelectric conversion layer 131, and the conductive film 112 functioning as an electrode. The conductive film 110, the photoelectric conversion layer 131, and the conductive film 112 are stacked in that order from the substrate 101 side. The photoelectric conversion layer 131 includes the p layer 133 and the n layer 135. The p layer 133 and the n layer 135 are stacked in that order from the conductive film 110 side, whereby a p-n junction is formed. In addition, the cell 105 includes the conductive film 120 functioning as an electrode, the photoelectric conversion layer 141b, and the conductive film 122 functioning as an electrode. The conductive film 120, the photoelectric conversion layer 141b, and the conductive film 122 are stacked in that order from the substrate 104 side. The photoelectric conversion layer 141b includes the p layer 143 and the n layer 145. The p layer 143 and the n layer 145 are stacked in that order from the conductive film 120 side, whereby a p-n junction is formed.

Thus, when the attention is focused on just the photoelectric conversion layer 131 and the photoelectric conversion layer 141b in the photoelectric conversion device illustrated in FIG. 3B, the p layer 133, the n layer 135, the n layer 145, and the p layer 143 are stacked in that order from the substrate 101 side. Thus, a photoelectric conversion device in which a p-n junction of the cell 102 and a p-n junction of the cell 105 are electrically connected in parallel can be manufactured. The fibrous body 106 is included in the structure body 103, which allows a photoelectric conversion device whose mechanical strength is increased to be realized.

Note that in FIG. 3B, the p layer 133 is closer to the substrate 101 than the n layer 135, and the p layer 143 is closer to the substrate 104 than the n layer 145; however, the disclosed invention is not limited to this structure. In the photoelectric conversion device according to one embodiment of the disclosed invention, the n layer 135 may be closer to the substrate 101 than the p layer 133, and the n layer 145 may be closer to the substrate 104 than the p layer 143.

Note that in the photoelectric conversion devices illustrated in FIGS. 3A and 3B, light may enter from the substrate 101 side or may enter from the substrate 104 side.

The case where the cell 102 and the cell 105 each include one unit cell, that is, one photoelectric conversion layer in each of the photoelectric conversion devices illustrated in FIGS. 3A and 3B is described as an example; however, the disclosed invention is not limited to this structure. Each of the cell 102 and the cell 105 may have a plurality of photoelectric conversion layers or a single photoelectric conversion layer. Note that in the case where the cell 102 has a plurality of photoelectric conversion layers, the plurality of photoelectric conversion layers are sequentially stacked from the substrate 101 side, and the p layer and the n layer in each of the photoelectric conversion layers included in the cell 102 provided between the substrate 101 and the structure body 103 are stacked in that order so as to be electrically connected in series.

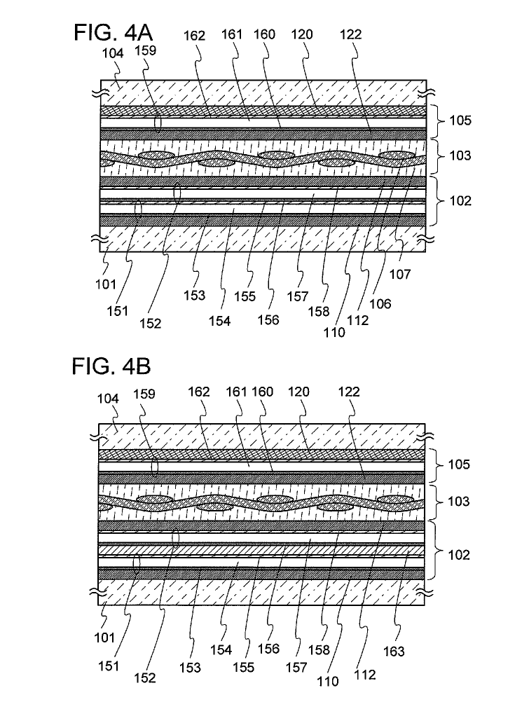

Next, each of FIGS. 4A and 4B is an example of a cross-sectional view of a photoelectric conversion device in which the cell 102 has a plurality of p-i-n junctions.

In the photoelectric conversion device illustrated in FIG. 4A, the cell 102 includes the conductive film 110 functioning as an electrode, a photoelectric conversion layer 151 (also referred to as a first photoelectric conversion layer), a photoelectric conversion layer 152 (also referred to as a second photoelectric conversion layer), and the conductive film 112 functioning as an electrode. The conductive film 110, the photoelectric conversion layer 151, the photoelectric conversion layer 152, and the conductive film 112 are stacked in that order from the substrate 101 side. The photoelectric conversion layer 151 includes a p layer 153 (also referred to as a first p-type semiconductor layer), an i layer 154 (also referred to as a first i-type semiconductor layer), and an n layer 155 (also referred to as a first n-type semiconductor layer). The p layer 153, the i layer 154, and the n layer 155 are stacked in that order from the conductive film 110 side, whereby a p-i-n junction is formed. The photoelectric conversion layer 152 includes a p layer 156 (also referred to as a second p-type semiconductor layer), an i layer 157 (also referred to as a second i-type semiconductor layer), and an n layer 158 (also referred to as a second n-type semiconductor layer). The p layer 156, the i layer 157, and the n layer 158 are stacked in that order from the conductive film 110 side, whereby a p-i-n junction is formed.

Thus, a multi-junction cell in which two unit cells, that is, the photoelectric conversion layer 151 and the photoelectric conversion layer 152 are stacked is used as the cell 102 in the photoelectric conversion device illustrated in FIG. 4A.

The cell 105 includes the conductive film 120 functioning as an electrode, a photoelectric conversion layer 159 (also referred to as a third photoelectric conversion layer), and the conductive film 122 functioning as an electrode. The conductive film 120, the photoelectric conversion layer 159, and the conductive film 122 are stacked in that order from the substrate 104 side. The photoelectric conversion layer 159 includes a p layer 160 (also referred to as a third p-type semiconductor layer), an i layer 161 (also referred to as a third i-type semiconductor layer), and an n layer 162 (also referred to as a third n-type semiconductor layer). The n layer 162, the i layer 161, and the p layer 160 are stacked in that order from the conductive film 120 side, whereby a p-i-n junction is formed. Thus, a photoelectric conversion device in which a p-i-n junction of the cell 102 and a p-i-n junction of the cell 105 are electrically connected in parallel can be manufactured. The fibrous body 106 is included in the structure body 103, which allows a photoelectric conversion device whose mechanical strength is increased to be realized.

Note that in the photoelectric conversion device illustrated in FIG. 4A, the photoelectric conversion layer 151 and the photoelectric conversion layer 152 are directly stacked; however, the disclosed invention is not limited to this structure. In the case where the cells each have a plurality of photoelectric conversion layers, a conductive intermediate layer may be provided between the photoelectric conversion layers.

FIG. 4B is an example of a cross-sectional view of a photoelectric conversion device having an intermediate layer between the photoelectric conversion layer 151 and the photoelectric conversion layer 152. Specifically, in the photoelectric conversion device illustrated in FIG. 4B, the cell 102 includes the conductive film 110 functioning as an electrode, the photoelectric conversion layer 151, an intermediate layer 163, the photoelectric conversion layer 152, and the conductive film 112 functioning as an electrode. The conductive film 110, the photoelectric conversion layer 151, the intermediate layer 163, the photoelectric conversion layer 152, and the conductive film 112 are stacked in that order from the substrate 101 side. The photoelectric conversion layer 151 includes the p layer 153, the i layer 154, and the n layer 155. The p layer 153, the i layer 154, and the n layer 155 are stacked in that order from the conductive film 110 side, whereby a p-i-n junction is formed. The photoelectric conversion layer 152 includes the p layer 156, the i layer 157, and the n layer 158. The p layer 156, the i layer 157, and the n layer 158 are stacked in that order from the conductive film 110 side, whereby a p-i-n junction is formed. Thus, a photoelectric conversion device in which sufficient conductivity between p-i-n junctions is ensured by the intermediate layer 163 and a p-i-n junction of the cell 102 and a p-i-n junction of the cell 105 are electrically connected in parallel can be manufactured. The fibrous body 106 is included in the structure body 103, which allows a photoelectric conversion device whose mechanical strength is increased to be realized.

The intermediate layer 163 can be formed using a light-transmitting conductive film. Specifically, the intermediate layer 163 can be formed from zinc oxide, titanium oxide, magnesium zinc oxide, cadmium zinc oxide, cadmium oxide, an In—Ga—Zn—O-based amorphous oxide semiconductor such as InGaO₃ZnO₅, or the like. Alternatively, a conductive material containing a mixed material of zinc oxide and aluminum nitride (referred to as a Zn—O—Al—N-based conductive material, and there is no particular limitation on component percentage of each element) may be used. Note that since the intermediate layer 163 has conductivity, the cell 102 included in the photoelectric conversion device illustrated in FIG. 4B also corresponds to a multi-junction cell in which two unit cells, that is, the photoelectric conversion layer 151 and the photoelectric conversion layer 152 are stacked, as illustrated in FIG. 4A.

Note that when the attention is focused on only the photoelectric conversion layer 151, the photoelectric conversion layer 152, and the photoelectric conversion layer 159 of each of the photoelectric conversion devices illustrated in FIGS. 4A and 4B, the p layer 153, the i layer 154, the n layer 155, the p layer 156, the i layer 157, the n layer 158, the p layer 160, the i layer 161, and the n layer 162 are stacked in that order from the substrate 101 side. However, the disclosed invention is not limited to this structure, and the p layer 160, the i layer 161, and the n layer 162 included in the photoelectric conversion layer 159 may be stacked in reverse order to that in the photoelectric conversion layer 159 illustrated in FIGS. 4A and 4B, in a manner similar to those of the photoelectric conversion devices illustrated in FIG. 2B and FIG. 3B. Alternatively, the p layer 153, the i layer 154, and the n layer 155 included in the photoelectric conversion layer 151, and the p layer 156, the i layer 157, and the n layer 158 included in the photoelectric conversion layer 152 may be stacked in reverse order to that in the photoelectric conversion layers illustrated in FIGS. 4A and 4B.

Note that in the photoelectric conversion devices illustrated in FIGS. 4A and 4B, light may enter from the substrate 101 side or may enter from the substrate 104 side. Note that it is preferable that the p layer 153 be closer to the light incident side than the n layer 155. The life of a hole as a carrier is as short as approximately half of the life of an electron as a carrier. When light enters the photoelectric conversion layer 151 having the p-i-n junction, a large number of electrons and holes are formed in the i layer 154, and the electrons move to the n layer 155 side and holes move to the p layer 153 side, so that electromotive force can be obtained. Accordingly, when light enters from the p layer 153 side, a large number of electrons and holes are formed in a region in the i layer 154, which is closer to the p layer 153 than to the n layer 155. Therefore, a distance to the p layer 153 to which the holes having short life move can be shortened; as a result, high electromotive force can be obtained. For the same reason, the p layer 156 is preferably closer to the light incident side than the n layer 158 and the p layer 160 is preferably closer to the light incident side than the n layer 162.

In each of FIGS. 4A and 4B, the case where the cell 102 has two photoelectric conversion layers (unit cells) is illustrated as an example; however, the cell 102 may have three or more photoelectric conversion layers. In each of FIGS. 4A and 4B, the case where the cell 105 has one photoelectric conversion layer (unit cell) is illustrated as an example; however, the cell 105 may have a plurality of photoelectric conversion layers in a manner similar to that of the cell 102. Note that a plurality of photoelectric conversion layers in each cell are sequentially stacked, and the p layer, the i layer, and the n layer in each of the photoelectric conversion layers included in the cell 102 and the cell 105 provided between one of the substrates 101 and 104 and the structure body 103 are stacked in that order so as to be electrically connected in series. In this manner, when a plurality of photoelectric conversion layers (unit cells) are connected in series, higher electromotive force can be obtained.

Note that light with a short wavelength has higher energy than light with a long wavelength. Accordingly, of the unit cell included in the cell 102 and the unit cell included in the cell 105 in each of the photoelectric conversion devices illustrated in FIG. 1, FIGS. 2A and 2B, FIGS. 3A and 3B, and FIGS. 4A and 4B, the unit cell which performs photoelectric conversion utilizing light in the short wavelength range is closer to the light incident side, whereby a loss of light in the short wavelength range generated in the photoelectric conversion device can be suppressed and conversion efficiency can be increased.

In each of the photoelectric conversion devices illustrated in FIG. 1, FIGS. 2A and 2B, FIGS. 3A and 3B, and FIGS. 4A and 4B, as the substrate 101 and the substrate 104, a glass substrate made of soda-lime glass, opaque glass, lead glass, tempered glass, ceramic glass, or the like. Further, a non-alkali glass substrate of aluminosilicate glass, barium borosilicate glass, aluminoborosilicate glass, or the like can be used; a quartz substrate; a ceramic substrate; or a metal substrate of stainless steel or the like can be used. There is a tendency that a flexible substrate formed using a synthetic resin such as plastics generally has a lower upper temperature limit than the above substrates; however, such a substrate can be used as long as it can withstand processing temperature in manufacturing steps. Note that an anti-reflective film may be provided on a light incident surface of a substrate. For example, a titanium oxide film or a titanium oxide film to which at least one metal element selected from copper, manganese, nickel, cobalt, iron, and zinc is added can be provided as the anti-reflective film. This anti-reflective film can be formed in such a manner that an organic solvent containing titanium oxide or containing the metal element and titanium oxide is applied to a glass substrate, and baking is performed at a temperature of from 60° C. to 300° C. in accordance with heat resistance of the substrate, so that the surface of the film has an uneven structure (also referred to as simply unevenness, an uneven portion, or a texture structure) with a thickness of 10 nm to 20 nm; preferably, minute unevenness such as cilia can be reduced. Such an anti-reflective film provided on a light incident surface of the substrate acts in such a way that reflection of incident light and adhesion of suspended particles (dust or the like) with a size of from approximately 2 μm to 10 μm are reduced and the conversion efficiency of the photoelectric conversion device is increased.

As examples of a plastic substrate, substrates including materials such as polyester typified by polyethylene terephthalate (PET); polyether sulfone (PES); polyethylene naphthalate (PEN); polycarbonate (PC); a polyamide synthetic fiber; polyether etherketone (PEEK); polysulfone (PSF); polyether imide (PEI); polyarylate (PAR); polybutylene terephthalate (PBT); polyimide; an acrylonitrile butadiene styrene resin; poly vinyl chloride; polypropylene; poly vinyl acetate; an acrylic resin; and the like can be given.

The p layers, the i layers, and the n layers included in the photoelectric conversion layers may be formed using a semiconductor having crystallinity such as a single crystal semiconductor, a polycrystalline semiconductor, or a microcrystalline semiconductor, or may be formed using an amorphous semiconductor. Silicon, silicon germanium, germanium, silicon carbide, or the like can be used as the photoelectric conversion layers.

Note that a microcrystalline semiconductor is a semiconductor having an intermediate structure between amorphous and crystalline structures (including single crystal and polycrystal). The microcrystalline semiconductor is a semiconductor having a third state which is stable in terms of free energy. For example, the microcrystalline semiconductor is a semiconductor having a crystal grain size of 2 nm to 200 nm inclusive, preferably 10 nm to 80 nm inclusive, more preferably 20 nm to 50 nm inclusive. The Raman spectrum of microcrystalline silicon, which is a typical example of a microcrystalline semiconductor, is shifted toward a shorter wavelength side than 520 cm⁻¹, which represents the Raman spectrum of single crystal silicon. That is, the peak of the Raman spectrum of microcrystalline silicon is within the range from 520 cm⁻¹ which represents single crystal silicon, to 480 cm⁻¹ which represents amorphous silicon. In addition, microcrystalline silicon contains hydrogen or halogen of at least 1 at. % or more in order to terminate dangling bonds. Moreover, the microcrystalline semiconductor may contain a rare gas element such as helium, argon, krypton, or neon to promote further lattice distortion, so that stability is increased and a favorable microcrystalline semiconductor can be obtained. Such a microcrystalline semiconductor has lattice distortion which changes the optical characteristics from the indirect transition of single crystal silicon into the direct transition. At least 10% of lattice distortion makes the optical characteristics change into the direct transition. When distortion exits locally, the optical characteristics in which the direct transition and the indirect transition are mixed can be obtained.

The semiconductor used for the i-layer is a semiconductor in which an impurity element imparting p-type or n-type conductivity is contained at a concentration less than or equal to 1×10²⁰/cm³, oxygen and nitrogen are contained at a concentration less than or equal to 9×10¹⁹/cm³, and photoconductivity is at least 100 times as high as the dark conductivity. The i-layer may contain boron at 1 ppm to 1000 ppm. The i-layer sometimes has weak n-type conductivity when an impurity element for controlling valence electrons is not added intentionally. This phenomenon remarkably appears when the i layer is formed using an amorphous semiconductor. Accordingly, when a photoelectric conversion layer having a p-i-n junction is formed, an impurity element imparting p-type conductivity may be added to the i layer at the same time as or after film formation. As the impurity element imparting p-type conductivity, boron is typically used, and an impurity gas such as B₂H₆ or BF₃ may be mixed into a semiconductor source gas at a ratio of 1 ppm to 1000 ppm. The concentration of boron may be, for example, 1×10¹⁴/cm³ to 6×10¹⁶/cm³.

Alternatively, when the i layer is formed after the p layer is formed, the impurity element imparting p-type conductivity included in the p layer can be diffused into the i layer. With the structure, even when the impurity element imparting p-type conductivity is not added to the i layer intentionally, valence electrons of the i layer can be controlled.

It is preferable that a layer on the light incident side be formed using a material having a small light absorption coefficient. For example, silicon carbide has a smaller light absorption coefficient than silicon. Accordingly, silicon carbide is used for the p layer or the n layer which is a layer closer to the light incident side, so that the amount of incident light which reaches the i layer can be increased; as a result, electromotive force of a solar cell can be raised.

Note that for the photoelectric conversion layers of the cell 102 and the cell 105, a material such as silicon or germanium can be used; however, the present invention disclosed herein is not limited to this structure. For example, as the cell 102 or the cell 105, a cell in which Cu, In, Ga, Al, Se, S, or the like is used for the photoelectric conversion layer and which is referred to as a CIS, CIGS, or chalcopyrite cell may be used. Alternatively, a CdTe—CdS cell with the use of a Cd compound for the photoelectric conversion layer may be used for the cell 102 or the cell 105. Like a dye-sensitized cell or an organic semiconductor cell, an organic-based cell with the use of an organic-based material for the photoelectric conversion layer may also be used for the cell 102 or the cell 105.

If light enters the photoelectric conversion device from the substrate 101 side, a transparent conductive material having a light-transmitting property, specifically, indium oxide, an alloy of indium tin oxide (ITO), zinc oxide, or the like is used for the conductive film 110 and the conductive film 112 in the cell 102 held by the substrate 101. Alternatively, a Zn—O—Al—N-based conductive material may be used. In addition, as for the cell 105 held by the substrate 104, a transparent conductive material having a light-transmitting property is used for the conductive film 122 which is the closest to a light source, in a manner similar to those of the conductive film 110 and the conductive film 112. In the cell 105 supported by the substrate 104, a conductive material which easily reflects light, specifically, aluminum, silver, titanium, tantalum, or the like is used for the conductive film 120 which is the most distant from the light source. Note that a transparent conductive material as described above may also be used for the conductive film 120. In this case, a film (a reflective film) with which light that passes through the cell 105 can be reflected to the cell 105 side is preferably formed on the substrate 104. For the reflective film, it is preferable to use a material which easily reflects light, such as aluminum, silver, titanium, or tantalum.

In the case where the conductive film 120 is formed using a conductive material which easily reflects light, by formation of unevenness on the surface which is in contact with the photoelectric conversion layer, light is reflected diffusely on the surface of the conductive film 120; thus, the light absorptance of the photoelectric conversion layer can be increased and conversion efficiency can be raised. In a similar manner, in the case where a reflective film is formed, when the surface of the reflective film from which light enters is made uneven, conversion efficiency can be raised.

Note that as the transparent conductive material, a conductive high molecular material (also referred to as conductive polymer) can be used instead of oxide metal such as indium oxide. As the conductive high molecular material, a π-electron conjugated high molecule can be used. For example, polyaniline and/or a derivative thereof, polypyrrole and/or a derivative thereof, polythiophene and/or a derivative thereof, and a copolymer of two or more kinds of those materials can be given.

For the organic resin 107 included in the structure body 103, a light-transmitting material which can surely transmit from the cell 102 to the cell 105 is used. As the organic resin 107, for example, a thermosetting resin such as an epoxy resin, an unsaturated polyester resin, a polyimide resin, a bismaleimide-triazine resin, or a cyanate resin can be used. Alternatively, a thermoplastic resin such as a polyphenylene oxide resin, a polyetherimide resin, or a fluorine resin can be used as the organic resin 107. Further alternatively, a plurality of resins selected from the above-described thermosetting resin and thermoplastic resin may be used as the organic resin 107. When the above organic resin is used, the fibrous body 106 can be firmly attached to the cell 102 and the cell 105 by heat treatment. The glass transition temperature of the organic resin 107 is preferably higher, in which case the mechanical strength of the cell 102 and the cell 105 with respect to local pressing force can be improved.

Highly thermally conductive filler may be dispersed in the organic resin 107 or the yarn bundle of the fibrous body 106. As the highly thermally conductive filler, aluminum nitride, boron nitride, silicon nitride, alumina, and the like can be given. As the highly thermally conductive filler, a metal particle such as silver or copper can also be given. When conductive filler is included in the organic resin or the yarn bundles of the fibrous body, heat generated in the cell 102 and the cell 105 can be easily released to the outside. Accordingly, thermal storage in the photoelectric conversion device can be controlled, and thus the photoelectric conversion efficiency can be prevented from being reduced and the photoelectric conversion device can be prevented from being damaged.

The fibrous body 106 is a woven fabric or a nonwoven fabric including high-strength fibers of an organic compound or an inorganic compound and is provided so as to overlap with the cell 102 and the cell 105. The high-strength fiber is specifically a fiber with a high modulus of elasticity in tension or a fiber with a high Young's modulus. As typical examples of the high-strength fiber, a polyvinyl alcohol fiber, a polyester fiber, a polyamide fiber, a polyethylene fiber, an aramid fiber, a polyparaphenylenebenzobisoxazole fiber, a glass fiber, a carbon fiber, and the like can be given. As a glass fiber, there is a glass fiber using E glass, S glass, D glass, Q glass, or the like. Note that the fibrous body 106 may be formed from one kind of the above high-strength fibers or a plurality of the above high-strength fibers.

Alternatively, the fibrous body 106 may be a woven fabric formed using bundles of fibers (single yarns) (hereinafter, the bundles of fibers are referred to as yarn bundles) for the warp yarn and the weft yarn, or a nonwoven fabric obtained by stacking yarn bundles of plural kinds of fibers in a random manner or in one direction. In the case of a woven fabric, a plain-woven fabric, a twilled fabric, a satin-woven fabric, or the like can be used as appropriate.

The cross-sectional shape of the yarn bundle may be circular or elliptical. As the yarn bundle of fibers, a yarn bundle of fibers may be used which has been subjected to fiber opening with a high-pressure water stream, high-frequency vibration using liquid as a medium, continuous ultrasonic vibration, pressing with a roller, or the like. A bundle of fibers which is subjected to fiber opening has a large width, has a smaller number of single yarns in the thickness direction, and has a cross section of a rectangular shape or a flat shape. Further, with the use of a loosely twisted yarn as the yarn bundle of fibers, the yarn bundle is easily flattened and has a rectangular shape or a flat shape in cross section. The use of a yarn bundle having a rectangular shape or a flat shape in cross section in this manner makes it possible to reduce the thickness of the fibrous body 106. Thus, the thickness of the structure body 103 can be reduced, and thus a thin photoelectric conversion device can be manufactured. As long as the diameter of the fiber falls within the range of 4 μm to 400 μm inclusive (preferably 4 μm to 200 μm inclusive), an effect of preventing destruction of the photoelectric conversion device due to pressing force can be sufficiently obtained. In principle, the above effect can be obtained even when the thickness is further reduced. Since the specific thickness depends on the material of the fiber, it is not limited to the above range.

In the drawings, the fibrous body 106 is shown as a woven fabric which is plain-woven using a yarn bundle having an elliptical shape in cross section.

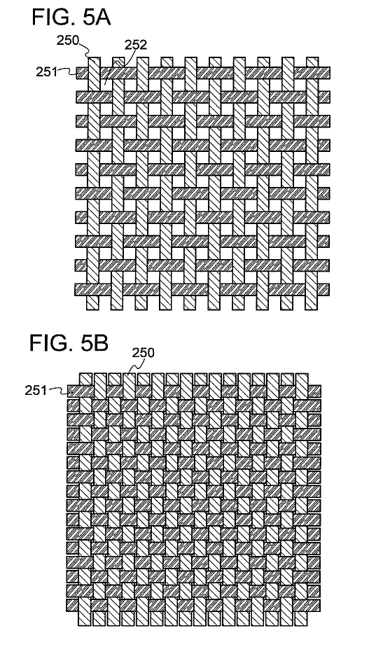

Each of FIGS. 5A and 5B is a top plan view of the fibrous body 106 which is a woven fabric formed using yarn bundles of fibers for the warp yarn and the weft yarn.

As illustrated in FIG. 5A, the fibrous body 106 is a woven using warp yarns 250 spaced at regular intervals and weft yarns 251 spaced at regular intervals. The fibrous body 106 which is a woven using the warp yarns 250 and the weft yarns 251 has regions without the wrap yarns 250 and the weft yarns 251 (basket holes 252). In the fibrous body 106, the fibrous body 106 is more easily impregnated with the organic resin 107, which results in an increase in the adhesion between the fibrous body 106 and the cells 102 and 105.

As illustrated in FIG. 5B, in the fibrous body 106, the density of the wrap yarns 250 and the weft yarns 251 may be high and the area occupied by the basket holes 252 may be small. Typically, it is preferable for each of the basket holes 252 to have an area smaller than that of a locally pressed portion. Typically, the basket hole 252 preferably has a rectangular shape having a side with a length of 0.01 mm to 0.2 mm inclusive. When the basket hole 252 in the fibrous body 106 has such a small area, pressure can be absorbed by the entire fibrous body 106 even when the fibrous body 106 is pressed by a member with a sharp tip. Thus, the mechanical strength of the cell can be effectively increased.

Further, in order to enhance permeability of an organic resin into the inside of the yarn bundle, the yarn bundle may be subjected to surface treatment. For example, as the surface treatment, corona discharge, plasma discharge, or the like for activating a surface of the yarn bundle can be given. Further, surface treatment using a silane coupling agent or a titanate coupling agent can be given.

In the structure body 103 used in the disclosed invention, a high-strength fiber with a high tensile modulus of elasticity or a high Young's modulus is used as the fibrous body 106. Thus, even when local pressure such as point pressure or linear pressure is applied, pressing force is dispersed throughout the fibrous body 106, and thus the photoelectric conversion layer, generation of cracks or the like of the conductive film, and the intermediate layer included in the cell, or a wiring which connects the cells can be controlled. Accordingly, the mechanical strength of the photoelectric conversion device can be increased.

In the photoelectric conversion device according to one embodiment of the disclosed invention, the structure body in which the fibrous body is impregnated with the organic resin, which is a so-called prepreg, is interposed between the plurality of cells, whereby the mechanical strength of the photoelectric conversion device against pressing force and the reliability thereof can be increased while light which enters the cells can be kept. In addition, the plurality of cells are connected in series, whereby a photoelectric conversion device having higher electromotive force than in the case of using a single cell can be manufactured. When a plurality of cells which absorb light with various wavelengths are used, a photoelectric conversion device which can convert sunlight including light in a wide range of wavelengths from ultraviolet rays to infrared rays into electrical energy with higher conversion efficiency without waste can be manufactured in a simpler process.

Different kinds of cells which are hard to be successively formed over one substrate in terms of a process can be stacked in the direction of travel of light in a simpler process. Thus, the photoelectric conversion device in which a plurality of cells which absorb light with various wavelengths can overlap with each other and which can convert sunlight including light in a wide range of wavelengths from ultraviolet rays to infrared rays into electrical energy with higher conversion efficiency without waste can be formed in a simpler process. Therefore, the manufacturing cost of manufacturing photoelectric conversion devices can be suppressed.

### Embodiment 2

In this embodiment, a method for manufacturing the photoelectric conversion device of the disclosed invention will be described using the photoelectric conversion device illustrated in FIG. 2A as an example.

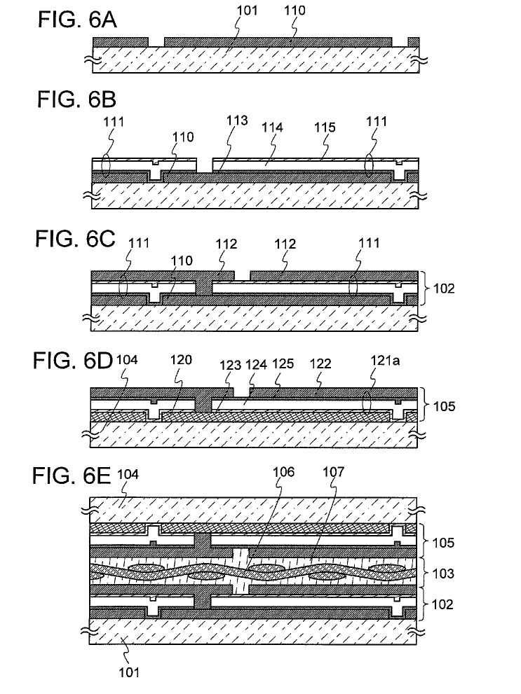

First, the formation of the cell 102 over the substrate 101 will be described. As illustrated in FIG. 6A, the conductive film 110 which is patterned (processed into a predetermined shape) is formed over the substrate 101. In this embodiment, since the photoelectric conversion device in which light enters from the substrate 101 side is described as an example, it is preferable that the substrate 101 have a property of transmitting visible light. As the substrate 101, for example, any of various commercial glass plates made of soda-lime glass, opaque glass, lead glass, tempered glass, ceramic glass, and the like can be used. Further, a non-alkali glass substrate of aluminosilicate glass, barium borosilicate glass, aluminoborosilicate glass, or the like; a quartz substrate; or a ceramic substrate can be used. There is a tendency that a flexible substrate (a plastic substrate) formed using a synthetic resin such as plastics generally has a lower upper temperature limit than the above substrates; however, such a substrate can be used as long as it can withstand processing temperature in manufacturing steps.

As a plastic substrate, polyester typified by polyethylene terephthalate (PET); polyethersulfone (PES); polyethylene naphthalate (PEN); polycarbonate (PC); a polyamide synthetic fiber; polyetheretherketone (PEEK); polysulfone (PSF); polyetherimide (PEI); polyarylate (PAR); polybutylene terephthalate (PBT); polyimide; an acrylonitrile butadiene styrene resin; polyvinyl chloride; polypropylene; polyvinyl acetate; an acrylic resin; and the like can be given.

In this embodiment, since the photoelectric conversion device in which light enters from the substrate 101 side is described as an example, the conductive film 110 can be formed using a conductive material having a property of transmitting visible light, for example, indium tin oxide (ITO), indium tin oxide containing silicon oxide (ITSO), organoindium, organotin, zinc oxide (ZnO), indium oxide containing zinc oxide (indium zinc oxide (IZO)), ZnO doped with gallium (Ga), tin oxide (SnO₂), indium oxide containing tungsten oxide, indium zinc oxide containing tungsten oxide, indium oxide containing titanium oxide, or indium tin oxide containing titanium oxide. Alternatively, as the conductive material having a light-transmitting property, a conductive high molecular material (also referred to as conductive polymer) can be used. As the conductive high molecular material, a π-electron conjugated high molecule can be used. For example, polyaniline and/or a derivative thereof, polypyrrole and/or a derivative thereof, polythiophene and/or a derivative thereof, and a copolymer of two or more kinds of those materials can be given.

The conductive film 110 is formed so as to have a thickness of from 40 nm to 800 nm, preferably from 400 nm to 700 nm. In addition, the sheet resistance of the conductive film 110 may be approximately 20 Ω/square to 200 Ω/square.

In this embodiment, a substrate manufactured by Asahi Glass Co., Ltd. (product name: Asahi-U) in which a 150-nm-thick silicon oxide film and an approximately-600-nm-thick conductive film of tin oxide whose surface has unevenness are sequentially stacked over the substrate 101 of soda-lime glass having a thickness of 1.1 mm is used. Then, the conductive film is patterned, so that the conductive film 110 which electrically connects a plurality of photoelectric conversion layers can be formed. Note that the conductive film 110 can be formed using an evaporation method in which a metal mask is used, a droplet discharge method, or the like, in addition to a method for patterning the conductive film using etching, a laser, or the like. Note that a droplet discharge method refers to a method in which droplets containing a predetermined composition are discharged or ejected from fine pores to form a predetermined pattern, and includes an ink-jet method and the like in its category.

When the surface of the conductive film 110 on the photoelectric conversion layer 111 side has unevenness, light is refracted or is reflected diffusely on the conductive film 110. Thus, light absorptance of the photoelectric conversion layer 111 can be increased and conversion efficiency can be increased.

Next, the photoelectric conversion layer 111 in which the p layer 113, the i layer 114, and the n layer 115 are stacked in that order is formed over the conductive film 110. Note that before the photoelectric conversion layer 111 is formed, brush cleaning, specifically, cleaning with chemical solution may be performed so that a foreign substance is removed, in order to improve the cleanliness of the surface of the conductive film 110. In addition, the surface may be cleaned using a chemical solution containing hydrofluoric acid or the like. In this embodiment, the surface of the conductive film 110 is cleaned with the above chemical solution, and then the surface of the conductive film 110 is cleaned using a hydrogen fluoride solution of 0.5%.

The p layer 113, the i layer 114, and the n layer 115 can be formed using an amorphous semiconductor, a polycrystalline semiconductor, a microcrystalline semiconductor, or the like by a sputtering method, an LPCVD method, a plasma CVD method, or the like. It is preferable that the p layer 113, the i layer 114, and the n layer 115 be formed in succession without being exposed to the air in order to prevent dust from being attached to their interfaces.

Alternatively, single crystal semiconductor thin films formed by an SOI method may be used as the p layer 113, the i layer 114, and the n layer 115. When a single crystal semiconductor thin film is used, the photoelectric conversion layer 111 has a small number of crystal defects which become a factor for inhibiting transport of carriers. Thus, conversion efficiency can be raised.

In this embodiment, an amorphous semiconductor containing silicon carbide, an amorphous semiconductor containing silicon, and a microcrystalline semiconductor containing silicon are used for the p layer 113, the i layer 114, and the n layer 115, respectively.

The amorphous semiconductor containing silicon carbide can be obtained by glow discharge decomposition of a gas containing carbon and a gas containing silicon. As the gas containing carbon, CH₄, C₂H₆, and the like can be given. As the gas containing silicon, SiH₄ and Si₂H₆ can be given. The gas containing silicon may be diluted with hydrogen or hydrogen and helium. When boron, for example, is used as an impurity element imparting p-type conductivity, borane, diborane, boron trifluoride, or the like is added to the gas containing carbon and the gas containing silicon, so that the amorphous semiconductor can have p-type conductivity. Specifically in this embodiment, the p layer 113 with a thickness of 10 nm is formed using a p-type amorphous semiconductor containing silicon carbide by a plasma CVD method under the following conditions: the flow rates of methane, monosilane, hydrogen, and diborane are 18 sccm, 6 sccm, 150 sccm, and 40 sccm, respectively; the reaction pressure is 67 Pa; the substrate temperature is 250° C.; and a high frequency of 13.56 MHz is used.

The amorphous semiconductor containing silicon can be obtained by glow discharge decomposition of the aforementioned gas containing silicon. Specifically in this embodiment, the i layer 114 with a thickness of 60 nm is formed using an amorphous semiconductor containing silicon by a plasma CVD method under the following conditions: the flow rates of monosilane and hydrogen are each 25 sccm; the reaction pressure is 40 Pa; the substrate temperature is 250° C.; and a high frequency of 60 MHz is used.

Note that before the i layer 114 is formed, plasma treatment using hydrogen is performed on the surface of the p layer 113, so that the number of crystal defects at the interface between the p layer 113 and the i layer 114 can be reduced and conversion efficiency can be increased. Specifically in this embodiment, plasma treatment is performed on the surface of the p layer 113 under the following conditions: the flow rate of hydrogen is 175 sccm, the reaction pressure is 67 Pa, the substrate temperature is 250° C., and a high frequency of 13.56 MHz is used. In the plasma treatment, argon may be added to hydrogen. In the case where argon is added, the flow rate thereof can be, for example, 60 sccm.

The microcrystalline semiconductor containing silicon can be formed by high-frequency plasma CVD with a high frequency of several tens to several hundreds of megahertz or with a microwave plasma CVD apparatus with a frequency higher than or equal to 1 GHz. Typically, when silicon hydride such as silane or disilane, silicon fluoride, or silicon chloride is diluted with hydrogen to be used, a microcrystalline semiconductor film can be formed. Further, silicon hydride, silicon fluoride, or silicon chloride may be diluted with hydrogen and one or more kinds of rare gases selected from helium, argon, krypton, and neon. The flow rate ratio of hydrogen to the compound containing silicon, such as silicon hydride, is set to be greater than or equal to 5:1 and less than or equal to 200:1, preferably greater than or equal to 50:1 and less than or equal to 150:1, more preferably 100:1. In the case where, for example, phosphorus is used as an impurity element imparting n-type conductivity, phosphine or the like may be added to a silicon-containing gas, so that a microcrystalline semiconductor can have n-type conductivity. Specifically in this embodiment, the n layer 115 with a thickness of 10 nm is formed using an amorphous semiconductor containing silicon by a plasma CVD method under the following conditions: the flow rates of monosilane, hydrogen, and phosphine are 5 sccm, 950 sccm, and 40 sccm, respectively; the reaction pressure is 133 Pa; the substrate temperature is 250° C.; and a high frequency of 13.56 MHz is used.

Note that in the case where indium tin oxide is used for the conductive film 110, when the i layer 114 which is an amorphous semiconductor is formed over the conductive film 110, hydrogen reduces indium tin oxide in the conductive film 110 when the i layer 114 is formed, which could lead to deterioration of film quality of the conductive film 110. In the case where indium tin oxide is used for the conductive film 110, in order to prevent indium tin oxide from being reduced, a film in which a conductive film with a thickness of several tens of nanometers using tin oxide or using a conductive material containing a mixed material of zinc oxide and aluminum nitride is stacked over the conductive film using indium tin oxide is preferably used as the conductive film 110.

As a semiconductor material used for the photoelectric conversion layer 111, germanium; a compound semiconductor such as gallium arsenide, indium phosphide, zinc selenide, gallium nitride, or silicon germanium can be used in addition to silicon or silicon carbide.

The photoelectric conversion layer 111 using a polycrystalline semiconductor can be formed by crystallization of an amorphous semiconductor film or a microcrystalline semiconductor film by a laser crystallization method, a thermal crystallization method, a thermal crystallization method in which a catalytic element which promotes crystallization, such as nickel, is used, or the like alone, or by any of the above methods in combination on an amorphous semiconductor film or a microcrystalline semiconductor film. Alternatively, a polycrystalline semiconductor may be formed directly by a sputtering method, a plasma CVD method, a thermal CVD method, or the like.

Then, as illustrated in FIG. 6B, the photoelectric conversion layer 111 in which the p layer 113, the i layer 114, and the n layer 115 are stacked in that order is patterned using etching, a laser, or the like. A plurality of the photoelectric conversion layers 111 which are patterned and separated are electrically connected to at least one conductive film 110 on the p layer 113 side.

Next, as illustrated in FIG. 6C, the conductive film 112 which is patterned is formed over the photoelectric conversion layer 111. In this embodiment, since the photoelectric conversion device in which light enters from the substrate 101 side is described as an example, it is preferable that the conductive material having a property of transmitting visible light be used for the conductive film 112, in a manner similar to that of the conductive film 110. The conductive film 112 is formed so as to have a thickness of 40 nm to 800 nm, preferably 400 nm to 700 nm. In addition, the sheet resistance of the conductive film 112 may be from approximately 20 Ω/square to 200 Ω/square. In this embodiment, the conductive film 112 with a thickness of approximately 600 nm is formed using tin oxide.

Note that the conductive film 112 which is patterned can be formed in such a manner that the conductive film is formed over the photoelectric conversion layer 111, and then the conductive film is patterned. Note that the conductive film 112 can be formed using an evaporation method in which a metal mask is used, a droplet discharge method, or the like, in addition to a method for patterning the conductive film using etching, a laser, or the like. The conductive film 112 is electrically connected to at least one of the plurality of the photoelectric conversion layers 111 which are separated by the patterning on the n layer 115 side. Then, the conductive film 110 which is electrically connected, on the p layer 113 side, to one photoelectric conversion layer 111 is electrically connected to the conductive film 112 which is electrically connected, on the n layer 115 side, to the photoelectric conversion layer 111 which is different from the one photoelectric conversion layer 111.

Note that the surface of the conductive film 112, which is on the side opposite to the side where the photoelectric conversion layer 111 is formed, may have unevenness. With the structure, light is refracted or is reflected diffusely on the conductive film 112. Thus, light absorptance of the photoelectric conversion layer 111 and the photoelectric conversion layer 121a to be formed later can be increased and conversion efficiency can be increased.

Next, the formation of the cell 105 over the substrate 104 will be described. As illustrated in FIG. 6D, the conductive film 120 which is patterned is formed over the substrate 104. In this embodiment, since the photoelectric conversion device in which light enters from the substrate 101 side is described as an example, a substrate having a low light-transmitting property such as a metal substrate having an insulating surface, in addition to the aforementioned substrate which can be used as the substrate 101, can be used for the substrate 104.

A conductive material which easily reflects light, specifically, aluminum, silver, titanium, tantalum, or the like is used for the conductive film 120. Note that the aforementioned conductive material having a light-transmitting property may also be used for the conductive film 120. In this case, a material with which light is easily reflected is preferably used for the substrate 104 or a film (a reflective film) with which light has passed through the cell 105 can be reflected to the cell 105 side is preferably formed over the substrate 104. The reflective film can be formed using aluminum, silver, titanium, tantalum, or the like.

In the case where the conductive film 120 is formed using a conductive material which easily reflects light, when unevenness is formed on the surface which is in contact with the photoelectric conversion layer 121a, light is reflected diffusely on the surface of the conductive film 120. Thus, the light absorptance of the photoelectric conversion layer 111 and the photoelectric conversion layer 121a can be increased and conversion efficiency can be increased. In a similar manner, in the case where a reflective film is formed, when the surface of the reflective film from which light enters is made uneven, conversion efficiency can be increased.

The conductive film 120 is formed so as to have a thickness of 40 nm to 800 nm, preferably 400 nm to 700 nm. In addition, the sheet resistance of the conductive film 120 may be approximately 20 Ω/square to 200 Ω/square. Specifically in this embodiment, a conductive film with a thickness of 300 nm formed using aluminum, a conductive film with a thickness of 100 nm formed using silver, and a conductive film with a thickness of 60 nm formed using zinc oxide containing aluminum are stacked by a sputtering method, and the stacked conductive films are used as the conductive film 120.

The conductive film 120 which is patterned can be formed in such a manner that the conductive film is formed over the substrate 104, and then the conductive film is patterned. Note that the conductive film 120 can be formed by an evaporation method in which a metal mask is used, a droplet discharge method, or the like, in addition to a method for patterning the conductive film using etching, a laser, or the like, in a manner similar to those of the conductive film 110 and the conductive film 112. The conductive film 120 which electrically connects a plurality of photoelectric conversion layers which are formed later can be formed by the above patterning.

Next, the photoelectric conversion layer 121a in which the n layer 123, the i layer 124, and the p layer 125 are stacked in that order is formed over the conductive film 120. Note that before the photoelectric conversion layer 121a is formed, brush cleaning, specifically, cleaning with chemical solution or the like may be performed so that a foreign substance is removed, in order to improve cleanliness of the surface of the conductive film 120. In addition, the surface may be cleaned using a chemical solution containing hydrofluoric acid or the like. In this embodiment, the surface of the conductive film 120 is cleaned with the above chemical solution, and then the surface of the conductive film 120 is cleaned using a hydrogen fluoride solution of 0.5%.

The n layer 123, the i layer 124, and the p layer 125 are stacked in reverse order to the n layer 115, the i layer 114, and the p layer 113 which are stacked; however, the n layer 123, the i layer 124, and the p layer 125 can be formed in manners similar to those of the n layer 115, the i layer 114, and the p layer 113, respectively. That is, the n layer 123, the i layer 124, and the p layer 125 can be formed using an amorphous semiconductor, a polycrystalline semiconductor, a microcrystalline semiconductor, or the like by a sputtering method, an LPCVD method, a plasma CVD method, or the like. It is preferable that the n layer 123, the i layer 124, and the p layer 125 be formed in succession without being exposed to the air in order to prevent dust or the like from being attached to their interfaces.

Alternatively, single crystal semiconductor thin films formed by an SOI method may be used as the n layer 123, the i layer 124, and the p layer 125. When a single crystal semiconductor thin film is used, the photoelectric conversion layer 121a has a small number of crystal defects which become a factor for inhibiting transport of carriers. Thus, conversion efficiency can be increased. In this embodiment, an amorphous semiconductor containing silicon carbide, an amorphous semiconductor containing silicon, and a microcrystalline semiconductor containing silicon are used for the p layer 125, the i layer 124, and the n layer 123, respectively.

For formation of the photoelectric conversion layer 111, plasma treatment is performed on the surface of the p layer 113 using hydrogen before the i layer 114 is formed in the case where the photoelectric conversion layer 111 is formed. However, for formation of the photoelectric conversion layer 121a, it is preferable that plasma treatment be performed using hydrogen on the surface of the i layer 124 after the i layer 124 is formed, and then the p layer 125 be formed. With the structure, the number of crystal defects at the interface between the p layer 125 and the i layer 124 can be reduced, and conversion efficiency can be increased. Specifically in this embodiment, plasma treatment is performed on the surface of the i layer 124 under the following conditions: the flow rate of hydrogen is 175 sccm, the reaction pressure is 67 Pa, the substrate temperature is 250° C., and a high frequency of 13.56 MHz is used. In the plasma treatment, argon may be added to hydrogen. In the case where argon is added, the flow rate thereof can be, for example, 60 sccm.

In this embodiment, light enters from the substrate 101 side; therefore, the thickness of the i layer 114 included in the photoelectric conversion layer 111, which is near a light source, is smaller than the thickness of the i layer 124 included in the photoelectric conversion layer 121a, which is distant from the light source. In this embodiment, over the conductive film 120, the n layer 123 with a thickness of 10 nm, the i layer 124 with a thickness of 300 nm, and the p layer 125 with a thickness of 10 nm are stacked in that order using an amorphous semiconductor containing silicon, an amorphous semiconductor containing silicon, and a p-type amorphous semiconductor containing silicon carbide, respectively.

Note that in the case where the i layer 114 is formed using an amorphous semiconductor containing silicon, the thickness of the i layer 114 is preferably from approximately 20 nm to 100 nm, more preferably from 50 nm to 70 nm. In the case where the i layer 114 is formed using a microcrystalline semiconductor containing silicon, the thickness of the i layer 114 is preferably from approximately 100 nm to 400 nm, preferably from 150 nm to 250 nm. When the i layer 114 is formed using a single crystal semiconductor containing silicon, the thickness of the i layer 114 is preferably from approximately 200 nm to 500 nm, preferably from 250 nm to 350 nm.

In the case where the i layer 124 is formed using an amorphous semiconductor containing silicon, the thickness of the i layer 124 is preferably approximately 200 nm to 500 nm, more preferably 250 nm to 350 nm. When the i layer 124 is formed using a microcrystalline semiconductor containing silicon, the thickness of the i layer 124 is preferably approximately 0.7 μm to 3 μm, more preferably 1 μm to 2 μm. When the i layer 124 is formed using a single crystal semiconductor containing silicon, the thickness of the i layer 124 is preferably approximately 1 μm to 100 μm, more preferably 8 μm to 12 μm.

Then, as illustrated in FIG. 6D, the photoelectric conversion layer 121a in which the n layer 123, the i layer 124, and the p layer 125 are stacked in that order is patterned using etching, a laser, or the like. A plurality of the photoelectric conversion layers 121a which are patterned and separated are electrically connected to at least one conductive film 120 on the n layer 123 side.

Next, the conductive film 122 which is patterned is formed over the photoelectric conversion layer 121a. In this embodiment, since the photoelectric conversion device in which light enters from the substrate 101 side is described as an example, it is preferable that the conductive material having a property of transmitting visible light be used for the conductive film 122, in a manner similar to those of the conductive film 110 and the conductive film 112. The conductive film 122 is formed so as to have a thickness of 40 nm to 800 nm, preferably 400 nm to 700 nm. In addition, the sheet resistance of the conductive film 122 may be from approximately 20 Ω/square to 200 Ω/square. In this embodiment, the conductive film 122 having a thickness of approximately 600 nm is formed using tin oxide.

Note that the conductive film 122 which is patterned can be formed in such a manner that the conductive film is formed over the photoelectric conversion layer 121a, and then the conductive film is patterned. Note that the conductive film 122 can be formed using an evaporation method in which a metal mask is used, a droplet discharge method, or the like, in addition to a method for patterning the conductive film using etching, a laser, or the like. The conductive film 122 is electrically connected to at least one of the plurality of the photoelectric conversion layers 121a which are separated by the patterning on the p layer 125 side. Then, the conductive film 120 which is electrically connected, on the n layer 123 side, to one photoelectric conversion layer 121a is electrically connected to the conductive film 122 which is electrically connected, on the p layer 125 side, to the photoelectric conversion layer 121a which is different from the one photoelectric conversion layer 121a.

Next, the substrate 101, the structure body 103, and the substrate 104 are stacked so that the cell 102 and the cell 105 face each other with the structure body 103 in which the fibrous body 106 is impregnated with the organic resin 107 interposed between the cell 102 and the cell 105. The structure body 103 is also referred to as a prepreg. The prepreg is specifically formed in the following manner: after the fibrous body 106 is impregnated with a varnish in which a matrix resin is diluted with an organic solvent, drying is performed so that the organic solvent is volatilized and the matrix resin is semi-cured. The thickness of the structure body 103 is 10 μm to 100 μm inclusive, preferably 10 μm to 30 μm inclusive. When the substrate 101 and the substrate 104 are flexible with the use of a structure body having such a thickness, a thin photoelectric conversion device which can be bent can be manufactured.

The structure body 103 in which a single-layer fibrous body 106 is impregnated with the organic resin is used in this embodiment; however, the disclosed invention is not limited to this structure. A structure body in which a stack of a plurality of fibrous bodies 106 is impregnated with an organic resin may be used. In the case where a plurality of structure bodies in each of which the single-layer fibrous body 106 is impregnated with an organic resin are stacked, another layer may be interposed between the structure bodies.

Then, as illustrated in FIG. 6E, the structure body 103 is subjected to heating and pressure bonding, so that the organic resin 107 of the structure body 103 is plasticized or cured. In the case where the organic resin 107 is an organic plastic resin, the organic resin which is plasticized is then cured by being cooled to room temperature. A step in which the structure body 103 is subjected to pressure bonding is performed under an atmospheric pressure or a reduced pressure.

The photoelectric conversion device illustrated in FIG. 2A can be formed manufactured by the above-described manufacturing method. In the photoelectric conversion device, the cell 102 includes a plurality of first stacks each including the conductive film 110, the photoelectric conversion layer 111, and the conductive film 112. P-n or p-i-n junctions of the plurality of first stacks are electrically connected in series. The cell 105 includes a plurality of second stacks each including the conductive film 120, the photoelectric conversion layer 121a, and the conductive film 122. P-n or p-i-n junctions of the plurality of second stacks are electrically connected in series. The p-n or p-i-n junction of each of the plurality of the first stacks and the p-n or p-i-n junction of each of the plurality of the second stacks are electrically connected in parallel in a region where the plurality of the first stacks, the structure body 103, and the plurality of the second stacks are not overlapped.

Note that the example in which the structure body 103 that is prepared in advance is firmly attached to the cell 102 and the cell 105 is described; however, the disclosed invention is not limited to this structure. The structure body 103 may be formed in such a manner that the cell 102 is placed over the fibrous body, and then the fibrous body is impregnated with the organic resin.

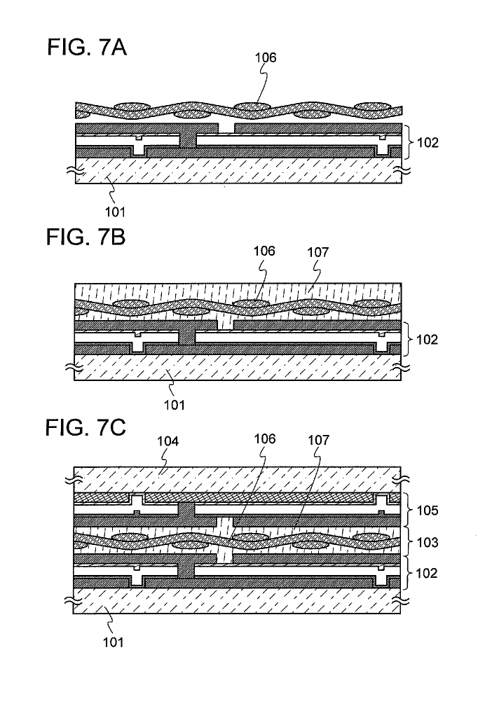

In the case where the structure body 103 is formed over the cell 102, the structure body 103 can be formed in the following manner. First, as illustrated in FIG. 7A, the fibrous body 106 is placed over the cell 102. After that, as illustrated in FIG. 7B, the fibrous body 106 is impregnated with the organic resin 107. As a method for impregnating the fibrous body 106 with the organic resin 107, a printing method, a cast method, a droplet discharge method, a dip coating method, or the like can be used. Note that the example in which the structure body 103 includes the single-layer fibrous body 106 is illustrated in FIG. 7C; however, the disclosed invention is not limited to this structure. The structure body 103 may include the fiber body 403 of two or more layers.

Next, the substrate 104 is superposed on the substrate 101 so that the cell 105 is in contact with the fibrous body 106 and the organic resin 107. After that, the organic resin 107 is heated to be plasticized or cured. Through the above steps, the structure body 103 which is firmly attached to the cell 102 and the cell 105 can be formed. In the case where the organic resin is an organic plastic resin, the organic resin which is plasticized is then cured by being cooled to room temperature.

In this embodiment, the method for manufacturing the photoelectric conversion device illustrated in FIG. 2A is described as an example; however, the disclosed invention is not limited to this structure. The photoelectric conversion devices illustrated in FIG. 2B, FIGS. 3A and 3B, and FIGS. 4A and 4B can also be formed by the manufacturing method described in this embodiment.

### Embodiment 3

In this embodiment, a structure in which a cell including a photoelectric conversion layer is formed over and adheres to a plastic substrate (a flexible substrate) will be described. Specifically, an example of the following structure will be described. In the structure, after a layer to be separated including a photoelectric conversion layer is formed over a supporting substrate having high heat resistance such as a glass substrate or a ceramic substrate with a separation layer and an insulating layer interposed therebetween, the supporting substrate and the layer to be separated are separated from each other using the separation layer, and the layer to be separated which is separated adheres to a plastic substrate to form a cell over the plastic substrate. In this embodiment, manufacture of a cell which is placed on the side opposite to the light incident side (a bottom cell) will be described. When a cell formed by a manufacturing method described in this embodiment is used as a cell placed on the light incident side (a top cell), the order of stacking electrodes and layers included in a photoelectric conversion layer may be changed as appropriate.

A photoelectric conversion layer in this embodiment refers to a layer including semiconductor layers for producing photoelectromotive force through light irradiation. That is to say, the photoelectric conversion layer refers to semiconductor layers in which a semiconductor junction typified by a p-n junction or a p-i-n junction is formed.

A photoelectric conversion layer is formed as a layer to be separated over a supporting substrate. In the photoelectric conversion layer, a first semiconductor layer (e.g., a p-type semiconductor layer), a second semiconductor layer (e.g., an i-type semiconductor layer), and a third semiconductor layer (e.g., an n-type semiconductor layer) are stacked over a conductive film serving as one electrode (a back electrode). Alternatively, in the photoelectric conversion layer, a first semiconductor layer (e.g., a p-type semiconductor layer) and a third semiconductor layer (e.g., an n-type semiconductor layer) may be stacked. As a semiconductor layer included in the photoelectric conversion layer, a semiconductor layer using amorphous silicon, microcrystalline silicon, or the like which can be formed without high heat treatment can be used. Also, a semiconductor layer using a crystalline semiconductor layer which needs a certain degree of heating or laser treatment, such as crystalline silicon, can be used with the use of a supporting substrate having high heat resistance. Thus, since semiconductor layers with different spectral sensitivity characteristics can be formed over a plastic substrate, conversion efficiency can be increased and portability can be increased along with a reduction in weight of the substrate.

As a typical example of an impurity element which is introduced to a semiconductor layer to convert the semiconductor layer into an n-type semiconductor layer, phosphorus, arsenic, antimony, and the like, which are elements belonging to Group 15 of the periodic table, are given. In addition, as a typical example of an impurity element which is introduced to a semiconductor layer to convert the semiconductor layer into a p-type semiconductor layer, boron, aluminum, and the like, which are elements belonging to Group 13 of the periodic table, are given.

In this embodiment, the first semiconductor layer, the second semiconductor layer, and the third semiconductor layer are illustrated with the same number and the same shape in a cross-sectional view of the photoelectric conversion layer which is shown as an example. However, in the case where the conductivity type of the second semiconductor layer is either p-type or n-type, a p-n junction is formed either between the first semiconductor layer and the second semiconductor layer or between the second semiconductor layer and the third semiconductor layer. The area of the p-n junction is preferably large so that carriers induced by light can move to the p-n junction without being recombined. Thus, the number and shape of the first semiconductor layer and the number and shape of the third semiconductor layer do not need to be the same. In addition, also in the case where the conductivity type of the second semiconductor layer is i-type, the area of the p-i junction is preferably large because the lifetime of a hole is shorter than that of an electron; thus, the number and shape of the first semiconductor layer and the number and shape of the third semiconductor layer do not need to be the same as in the case of the p-n junction.

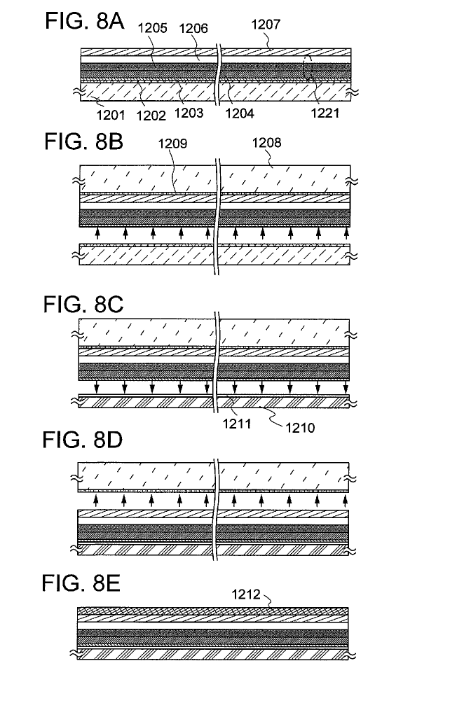

FIGS. 8A to 8E illustrate an example of a manufacturing process of a cell including a photoelectric conversion layer.

First, over a supporting substrate 1201 having an insulating surface, an insulating layer 1203, a conductive film 1204, and a photoelectric conversion layer 1221 including a first semiconductor layer 1205 (e.g., a p-type semiconductor layer), a second semiconductor layer 1206 (e.g., an i-type semiconductor layer), a third semiconductor layer 1207 (e.g., an n-type semiconductor layer), and the like are formed, with a separation layer 1202 interposed therebetween (see FIG. 8A).

As the supporting substrate 1201, a glass substrate, a quartz substrate, a sapphire substrate, a ceramic substrate, a metal substrate provided with an insulating layer on the surface, or the like, which is a substrate having high heat resistance can be used.

The separation layer 1202 is formed with a single layer or stacked layers by a sputtering method, a plasma CVD method, a coating method, a printing method, or the like using an element selected from tungsten (W), molybdenum (Mo), titanium (Ti), tantalum (Ta), niobium (Nb), nickel (Ni), cobalt (Co), zirconium (Zr), zinc (Zn), ruthenium (Ru), rhodium (Rh), palladium (Pd), osmium (Os), iridium (Ir), and silicon (Si), or an alloy material or a compound material containing such an element as its main component. The crystal structure of a layer containing silicon may be amorphous, microcrystalline, or polycrystalline. Note that a coating method includes a spin-coating method, a droplet discharge method, a dispensing method, a nozzle-printing method, and a slot die coating method in its category here.

In the case where the separation layer 1202 has a single-layer structure, it is preferable to form a tungsten layer, a molybdenum layer, or a layer containing a mixture of tungsten and molybdenum. Alternatively, a layer containing an oxide or an oxynitride of tungsten, a layer containing an oxide or an oxynitride of molybdenum, or a layer containing an oxide or an oxynitride of a mixture of tungsten and molybdenum is formed. Note that the mixture of tungsten and molybdenum corresponds to, for example, an alloy of tungsten and molybdenum.

In the case where the separation layer 1202 has a stacked-layer structure, it is preferable to form, as a first layer, a tungsten layer, a molybdenum layer, or a layer containing a mixture of tungsten and molybdenum, and to form, as a second layer, a layer of an oxide, a nitride, an oxynitride, or a nitride oxide of tungsten, molybdenum, or a mixture of tungsten and molybdenum.

In the case where the separation layer 1202 is formed as a stacked-layer structure of a layer containing tungsten and a layer containing an oxide of tungsten, by formation of a layer containing tungsten and an insulating layer formed using an oxide thereover, a layer containing an oxide of tungsten is formed at the interface between the tungsten layer and the insulating layer. Alternatively, a layer containing an oxide of tungsten may be formed in such a manner that the surface of the layer containing tungsten may be subjected to thermal oxidation treatment, oxygen plasma treatment, treatment using a strong oxidizing solution such as ozone water, or the like. Plasma treatment or heat treatment may be performed in an atmosphere of oxygen, dinitrogen monoxide, or a mixed gas of such a gas and another gas. The same can be applied to the case of forming a layer containing a nitride, an oxynitride, or a nitride oxide of tungsten. After a layer containing tungsten is formed, a silicon nitride layer, a silicon oxynitride layer, or a silicon nitride oxide layer may be formed thereover.

The insulating layer 1203 serving as a base can be formed with a single layer or plural layers of an inorganic insulating film such as a silicon oxide film, a silicon nitride film, a silicon oxynitride film, or a silicon nitride oxide film.

In this specification, silicon oxynitride refers to a substance that contains a larger amount of oxygen than that of nitrogen. For example, silicon oxynitride contains oxygen, nitrogen, silicon, and hydrogen at concentrations ranging from 50 at. % to 70 at. % inclusive, from 0.5 at. % to 15 at. % inclusive, from 25 at. % to 35 at. % inclusive, and from 0.1 at. % to 10 at. % inclusive, respectively. In addition, silicon nitride oxide refers to a substance that contains a larger amount of nitrogen than that of oxygen. For example, silicon nitride oxide contains oxygen, nitrogen, silicon, and hydrogen at concentrations ranging from 5 at. % to 30 a. % inclusive, from 20 at. % to 55 at. % inclusive, from 25 at. % to 35 at. % inclusive, and from 10 at. % to 25 at. % inclusive, respectively. Note that the percentages of oxygen, nitrogen, silicon, and hydrogen fall within the aforementioned ranges in the case where measurement is performed using Rutherford backscattering spectrometry (RBS) or hydrogen forward scattering (HFS). Moreover, the total of the percentages of the constituent elements does not exceed 100 at. %.

It is preferable to form the conductive film 1204 using a metal film having high reflectivity, such as aluminum, silver, titanium, or tantalum. Note that an evaporation method or a sputtering method can be used for the formation of the conductive film 1204. In addition, the conductive film 1204 may be formed using a plurality of layers. For example, a buffer layer or the like for improving the adhesiveness between the conductive film 1204 and the first semiconductor layer 1205 may be formed and stacked using a metal film, a metal oxide film, a metal nitride film, or the like. Furthermore, the surface of the conductive film 1204 may be processed by etching treatment or the like to have a texture structure (an uneven structure). When the surface of the conductive film 1204 has a texture structure, reflection of light can be diffused, so that incident light can be efficiently converted into electric energy. Note that the texture structure refers to an uneven structure which prevents reflection of incident light and with which the amount of light which enters the photoelectric conversion layer can be increased by diffusing reflection of light and the conversion efficiency can be improved.

The first semiconductor layer 1205, the second semiconductor layer 1206, and the third semiconductor layer 1207 can be formed using any of the following materials: an amorphous semiconductor formed by a vapor-phase growth method using a semiconductor source gas typified by silane or germane or a sputtering method; a polycrystalline semiconductor formed by crystallization of the amorphous semiconductor with the use of light energy or thermal energy; a microcrystalline (also referred to as semiamorphous or microcrystal) semiconductor; and the like. The semiconductor layer can be formed by a sputtering method, an LPCVD method, a plasma CVD method, or the like.

A microcrystalline semiconductor film has a metastable state of an intermediate structure between an amorphous structure and a single crystal structure when Gibbs free energy is considered. That is, the microcrystalline semiconductor film includes a semiconductor having a third state which is stable in terms of free energy and has a short range order and lattice distortion. Columnar-like or needle-like crystals grow in a normal direction with respect to the substrate surface. The Raman spectrum of microcrystalline silicon, which is a typical example of the microcrystalline semiconductor, is shifted to a smaller wavenumber than 520 cm⁻¹ which represents single crystal silicon. That is, the peak of the Raman spectrum of microcrystalline silicon exists between 520 cm⁻¹ which represents single crystal silicon and 480 cm⁻¹ which represents amorphous silicon. In addition, microcrystalline silicon contains hydrogen or halogen of at least 1 at. % in order to terminate a dangling bond. Moreover, microcrystalline silicon contains a rare gas element such as helium, argon, krypton, or neon to further promote lattice distortion, so that stability is increased and a favorable microcrystalline semiconductor film can be obtained.

Typical examples of an amorphous semiconductor include hydrogenated amorphous silicon, while typical examples of a crystalline semiconductor include polysilicon. Examples of polysilicon (polycrystalline silicon) include so-called high-temperature polysilicon which contains polysilicon as a main component and is formed at a process temperature of greater than or equal to 800° C., so-called low-temperature polysilicon that contains polysilicon as a main component and is formed at a process temperature of less than or equal to 600° C., polysilicon obtained by crystallizing amorphous silicon by using an element promoting crystallization or the like, and the like. Needless to say, a microcrystalline semiconductor or a semiconductor partly including a crystalline phase can also be used as described above.

In addition, the first semiconductor layer 1205, the second semiconductor layer 1206, and the third semiconductor layer 1207 can also be formed using, in addition to silicon and silicon carbide, germanium or a compound semiconductor such as gallium arsenide, indium phosphide, zinc selenide, gallium nitride, or silicon germanium.

In the case of using a crystalline semiconductor layer for the semiconductor layer, the crystalline semiconductor layer may be formed by any of various methods such as a laser crystallization method and a thermal crystallization method. The amorphous semiconductor layer may be crystallized by using a combination of heat treatment and laser light irradiation. The heat treatment or the laser light irradiation may be carried out several times, separately.

The crystalline semiconductor layer may be directly formed over a substrate by a plasma CVD method. Alternatively, the crystalline semiconductor layer may be selectively formed over a substrate by a plasma CVD method. Note that the crystalline semiconductor layer is preferably formed over the supporting substrate 1201 so as to have a columnar structure in which crystals grow into a columnar shape.

Note that an impurity element imparting a first conductivity type (e.g., p-type conductivity) is introduced to one of the first semiconductor layer 1205 and the third semiconductor layer 1207, and an impurity element imparting a second conductivity type (e.g., n-type conductivity) is introduced to the other. In addition, preferably, the second semiconductor layer 1206 is either an intrinsic semiconductor layer or a layer to which the impurity element imparting the first or second conductivity type is added. In this embodiment, an example in which three semiconductor layers are stacked to form a p-i-n junction as the photoelectric conversion layer is described; however, plural semiconductor layers may also be stacked to form other junction such as a p-n junction.

Through the above steps, over the separation layer 1202 and the insulating layer 1203, the conductive film 1204 and the photoelectric conversion layer 1221 including the first semiconductor layer 1205, the second semiconductor layer 1206, the third semiconductor layer 1207, and the like can be formed.

Then, the layer to be separated which includes the conductive film 1204, the first semiconductor layer 1205, the second semiconductor layer 1206, and the third semiconductor layer 1207 over the insulating layer 1203 is attached to a temporary supporting substrate 1208 using an adhesive for separation 1209, and the layer to be separated is separated from the supporting substrate 1201 using the separation layer 1202. By this process, the layer to be separated is placed on the temporary supporting substrate 1208 side (see FIG. 8B).

As the temporary supporting substrate 1208, a glass substrate, a quartz substrate, a sapphire substrate, a ceramic substrate, a metal substrate, or the like can be used. In addition, a plastic substrate having heat resistance to withstand the processing temperature in this embodiment, or a flexible substrate such as a film may also be used.

In addition, as the adhesive for separation 1209 which is used here, an adhesive which is soluble in water or a solvent, an adhesive which is capable of being plasticized upon irradiation with UV light or the like is used so that the temporary supporting substrate 1208 and the layer to be separated can be chemically or physically separated from each other when necessary.

The above process of transferring the layer to be separated to the temporary supporting substrate, which is shown as an example, may also be carried out by another method. For example, any of the following methods can be used as appropriate: a method in which a separation layer is formed between a substrate and a layer to be separated, a metal oxide film is provided between the separation layer and the layer to be separated, and the metal oxide film is weakened by crystallization to perform separation of the layer to be separated; a method in which an amorphous silicon film containing hydrogen is provided between a highly heat-resistant supporting substrate and a layer to be separated, and the amorphous silicon film is removed by laser light irradiation or etching to perform separation of the layer to be separated; a method in which a separation layer is formed between a supporting substrate and a layer to be separated, a metal oxide film is provided between the separation layer and the layer to be separated, the metal oxide film is weakened by crystallization, and part of the separation layer is etched away using a solution or a halogen fluoride gas such as NF₃, BrF₃, or ClF₃ to perform separation at the weakened metal oxide film; a method in which a supporting substrate provided with a layer to be separated is mechanically removed or is etched away using a solution or a halogen fluoride gas such as NF₃, BrF₃, or ClF₃; and the like. In addition, it is also possible to use a method in which a film containing nitrogen, oxygen, hydrogen, or the like (e.g., an amorphous silicon film containing hydrogen, a film of an alloy containing hydrogen, or a film of an alloy containing oxygen) is used as a separation layer, which is irradiated with laser light, so that nitrogen, oxygen, or hydrogen contained in the separation layer is released as a gas to promote separation between a layer to be separated and a substrate.

When a plurality of the above-described separation methods are combined, the transfer process can be performed easily. That is, the separation can be performed with physical force (by a machine or the like) after performing laser light irradiation; etching on the separation layer with a gas, a solution, or the like; or mechanical removal with a sharp knife, scalpel, or the like so as to make a condition where the separation layer and the layer to be separated can be easily separated from each other.

Further, the layer to be separated may also be separated from the supporting substrate after liquid is made to permeate the interface between the separation layer and the layer to be separated, or while liquid such as water or ethanol is poured on this interface.

Furthermore, in the case where the separation layer 1202 is formed using tungsten, it is preferable that the separation be performed while etching the separation layer using a mixed solution of ammonium water and a hydrogen peroxide solution.

Next, the layer to be separated which is separated from the supporting substrate 1201 and in which the separation layer 1202 or the insulating layer 1203 is exposed adheres to a plastic substrate 1211 using an adhesive layer 1210 (see FIG. 8C).

As a material for the adhesive layer 1210, any of a variety of curable adhesives, such as a reactive curable adhesive, a thermal curable adhesive, a photo curable adhesive such as an ultraviolet curable adhesive, and an anaerobic adhesive can be used.

As the plastic substrate 1211, any of a variety of substrates having flexibility and a light-transmitting property with respect to visible light can be used, and a film of an organic resin or the like is preferably used. As the organic resin, for example, an acrylic resin, a polyester resin such as polyethylene terephthalate (PET) or polyethylene naphthalate (PEN), a polyacrylonitrile resin, a polyimide resin, a polymethyl methacrylate resin, a polycarbonate (PC) resin, a polyethersulfone (PES) resin, a polyamide resin, a cycloolefin resin, a polystyrene resin, a polyamide imide resin, a polyvinylchloride resin, or the like can be used.

Over the plastic substrate 1211, a protective layer having low permeability, such as a film containing nitrogen and silicon such as silicon nitride or silicon oxynitride, or a film containing nitrogen and aluminum such as aluminum nitride may be formed in advance.

After that, the temporary supporting substrate 1208 is removed by dissolving or plasticizing the adhesive for separation 1209 (see FIG. 8D). Then, after performing processing of the photoelectric conversion layer 1221 into a desired shape and the like, a conductive film 1212 which serves as the other electrode (surface electrode) is formed over the third semiconductor layer 1207 (see FIG. 8E).

In the above-described manner, the cell including the photoelectric conversion layer can be transferred to a substrate such as a plastic substrate. The cell including the photoelectric conversion layer in this embodiment may be attached to a cell including another photoelectric conversion layer using a structure body in which a fibrous body is impregnated with an organic resin as described in the above embodiment, whereby a photoelectric conversion device can be manufactured.

Note that the conductive film 1212 can be formed by a sputtering method or a vacuum evaporation method. The conductive film 1212 is preferably formed using a material that transmits light sufficiently. Examples of the above material include indium tin oxide (ITO), indium tin oxide containing silicon oxide (ITSO), organic indium, organic tin, zinc oxide (ZnO), indium oxide containing zinc oxide (indium zinc oxide (IZO)), ZnO doped with gallium (Ga), tin oxide (SnO₂), indium oxide containing tungsten oxide, indium zinc oxide containing tungsten oxide, indium oxide containing titanium oxide, and indium tin oxide containing titanium oxide. In addition, as the conductive material having a light-transmitting property, a conductive high molecular material (also referred to as conductive polymer) can be used. As the conductive high molecular material, π electron conjugated conductive polymer can be used. For example, polyaniline and/or a derivative thereof, polypyrrole and/or a derivative thereof, polythiophene and/or a derivative thereof, a copolymer of two or more kinds of those materials, and the like can be given.

Note that this embodiment can be combined with any of the other embodiments as appropriate.

### Embodiment 4

This embodiment relates to a method for manufacturing a cell including a photoelectric conversion layer by bonding a single crystal semiconductor substrate to a supporting substrate made of glass, ceramic, or the like, and one example thereof will be described. In this embodiment, manufacture of a cell which is placed on the side opposite to the light incident side (a bottom cell) will be described. When a cell formed by a manufacturing method described in this embodiment is used as a cell placed on the light incident side (a top cell), the order of stacking electrodes and layers included in a photoelectric conversion layer may be changed as appropriate.

A fragile layer is formed in a single crystal semiconductor substrate which is to be attached to a supporting substrate. Over the single crystal semiconductor substrate, a conductive film serving as one electrode (a back electrode), a photoelectric conversion layer in which a first semiconductor layer, a second semiconductor layer, and a third semiconductor layer are stacked, and an insulating layer to be bonded to the supporting substrate are formed in advance. Then, the supporting substrate and the insulating layer are closely attached to each other, and then, separation is performed around the fragile layer, whereby a photoelectric conversion device in which a single crystal semiconductor layer is used as the semiconductor layers in the photoelectric conversion layer can be manufactured over the supporting substrate. Accordingly, a cell including a photoelectric conversion layer with fewer crystal defects which could inhibit carrier transfer can be manufactured, and the photoelectric conversion device can have excellent conversion efficiency.

In this embodiment, the first semiconductor layer, the second semiconductor layer, and the third semiconductor layer are illustrated with the same number and the same shape in a cross-sectional view of the photoelectric conversion layer which is shown as an example. However, in the case where the conductivity type of the second semiconductor layer is either p-type or n-type, a p-n junction is formed either between the first semiconductor layer and the second semiconductor layer or between the second semiconductor layer and the third semiconductor layer. The area of the p-n junction is preferably large so that carriers induced by light can move to the p-n junction without being recombined. Thus, the number and shape of the first semiconductor layer and the number and shape of the third semiconductor layer do not need to be the same. In addition, also when the conductivity type of the second semiconductor layer is i-type, the area of the p-i junction is preferably large because the lifetime of a hole is shorter than that of an electron; thus, the number and shape of the first semiconductor layer and the number and shape of the third semiconductor layer do not need to be the same as in the case of the p-n junction.

Note that an impurity element imparting a first conductivity type (e.g., p-type conductivity) is introduced to one of the first semiconductor layer and the third semiconductor layer, and an impurity element imparting a second conductivity type (e.g., n-type conductivity) is introduced to the other. In addition, preferably, the second semiconductor layer is either an intrinsic semiconductor layer or a layer to which the impurity element imparting the first or second conductivity type is added. In this embodiment, an example in which three semiconductor layers are stacked as the photoelectric conversion layer is described; however, plural semiconductor layers may also be stacked to form other junction such as a p-n junction.

Note that the term “fragile layer” in this specification refers to a region at which a single crystal semiconductor substrate is separated into a single crystal semiconductor layer and a separation substrate (a single crystal semiconductor substrate) in a separation step, and its vicinity. The state of the fragile layer depends on a means for forming the fragile layer. For example, the fragile layer refers to a layer which is weakened by local disorder of the crystal structure. Note that there may be a case where a region ranging from one surface of a single crystal semiconductor substrate to the fragile layer is weakened to some extent; however, the fragile layer in this specification refers to a region at which separation is performed later and its vicinity.

Note that a “single crystal semiconductor” here refers to a semiconductor in which crystal faces and crystal axes are aligned, and constituent atoms or molecules are aligned in a spatially ordered manner. Note that a single crystal semiconductor also includes a semiconductor having irregularity such as a semiconductor having a lattice defect in which the alignment of atoms or molecules is partly disordered or a semiconductor having intended or unintended lattice distortion.

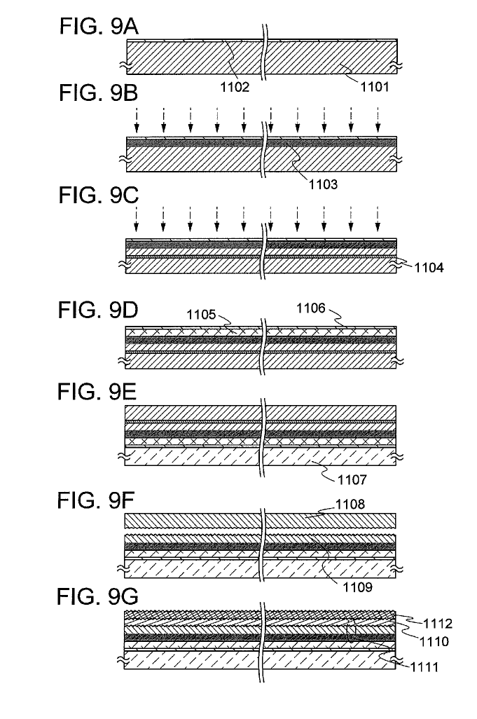

FIGS. 9A to 9G illustrate an example of a manufacturing process of a cell including a photoelectric conversion layer in this embodiment.

First, a protective layer 1102 is formed over one surface of a single crystal semiconductor substrate 1101 having a first conductivity type (see FIG. 9A). Then, an impurity element imparting the first conductivity type is introduced through the surface of the protective layer 1102, thereby forming a first semiconductor layer 1103 to which the impurity element imparting the first conductivity type is introduced (see FIG. 9B).

Although the above description shows that the single crystal semiconductor substrate 1101 has the first conductivity type, the conductivity type of the single crystal semiconductor substrate 1101 is not particularly limited thereto. It is preferable that the concentration of the impurity element introduced to the single crystal semiconductor substrate 1101 be lower than the concentration of an impurity element imparting a conductivity type which is introduced to the first semiconductor layer and the third semiconductor layer which are formed later.

As the single crystal semiconductor substrate 1101, a semiconductor wafer of silicon, germanium, or the like; a compound semiconductor wafer of gallium arsenide, indium phosphide, or the like; and the like can be used. In particular, a single crystal silicon wafer is preferably used. The planar shape of the single crystal semiconductor substrate 1101 is not limited to a particular shape but is desirably a rectangular shape in the case where a supporting substrate to which the single crystal semiconductor substrate 1101 is fixed later has a rectangular shape. Further, the surface of the single crystal semiconductor substrate 1101 is desirably polished to be a mirror surface.

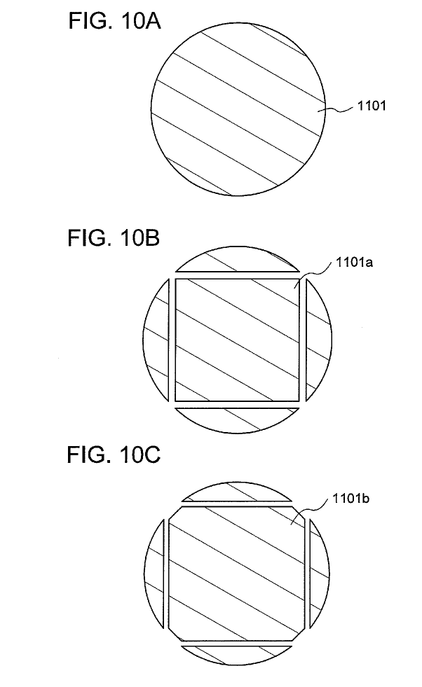

Many of single crystal silicon wafers on the market are circular in shape. When such a circular wafer is used, it may be processed to have a rectangular shape or a polygonal shape. For example, as illustrated in FIG. 10A to 10C, a single crystal semiconductor substrate 1101a with a rectangular shape (see FIG. 10B) or a single crystal semiconductor substrate 1101b with a polygonal shape (see FIG. 10C) can be cut out from a circular single crystal semiconductor substrate 1101 (see FIG. 10A).

Note that FIG. 10B illustrates the case where the single crystal semiconductor substrate 1101a is cut out to have a rectangular shape of the maximum size, which is inscribed in the circular single crystal semiconductor substrate 1101. Here, the angle of each corner of the single crystal semiconductor substrate 1101a is about 90 degrees. FIG. 10C illustrates the case where the single crystal semiconductor substrate 1101b is cut out so that the distance between the opposing lines is longer than that of the single crystal semiconductor substrate 1101a. In that case, the angle of each corner of the single crystal semiconductor substrate 1101b is not 90 degrees, and the single crystal semiconductor substrate 1101b does not have a rectangular shape but has a polygonal shape.

As the protective layer 1102, silicon oxide or silicon nitride is preferably used. As a method for forming the protective layer 1102, for example, a plasma CVD method, a sputtering method, or the like may be employed. In addition, the protective layer 1102 can also be formed by oxidizing the single crystal semiconductor substrate 1101 with oxidizing chemicals or oxygen radicals. Further, the protective layer 1102 may be formed by oxidizing the surface of the single crystal semiconductor substrate 1101 by a thermal oxidation method. By the formation of the protective layer 1102, it is possible to prevent the substrate surface from being damaged at the time of forming the fragile layer in the single crystal semiconductor substrate 1101 or adding the impurity element imparting one conductivity type to the single crystal semiconductor substrate 1101.

The first semiconductor layer 1103 is formed by introducing the impurity element imparting the first conductivity type to the single crystal semiconductor substrate 1101. Since the protective layer 1102 is formed over the single crystal semiconductor substrate 1101, the impurity element imparting the first conductivity type is introduced to the single crystal semiconductor substrate 1101 through the protective layer 1102.

As the impurity element imparting the first conductivity type, an element belonging to Group 13 of the periodic table, for example, boron is used. Consequently, the first semiconductor layer 1103 having p-type conductivity can be formed. Note that the first semiconductor layer 1103 can also be formed by a thermal diffusion method. Note that a thermal diffusion method should be performed before the formation of the fragile layer because high-temperature treatment with a temperature of about 900° C. or more is performed.

The first semiconductor layer 1103 formed by the foregoing method is disposed on the side opposite to the light incident side. Here, in the case of using a p-type substrate as the single crystal semiconductor substrate 1101, the first semiconductor layer 1103 is a high-concentration p-type region. Accordingly, the high-concentration p-type region and a low-concentration p-type region are disposed in order from the side opposite to the light incident side, so that a back surface field (BSF) is formed. That is, electrons cannot enter the high-concentration p-type region and thus recombination of carriers generated by photoexcitation can be reduced.

Next, ion irradiation is performed through the surface of the protective layer 1102, so that a fragile layer 1104 is formed in the single crystal semiconductor substrate 1101 (see FIG. 9C). Here, as the ions, ions generated using a source gas containing hydrogen (in particular, H⁺ ions, H₂⁺ ions, H₃⁺ ions, or the like) are preferably used. Note that the depth at which the fragile layer 1104 is formed is controlled by an acceleration voltage at the time of ion irradiation. Further, the thickness of a single crystal semiconductor layer to be separated from the single crystal semiconductor substrate 1101 depends on the depth at which the fragile layer 1104 is formed.

The depth at which the fragile layer 1104 is formed is less than or equal to 500 nm, preferably less than or equal to 400 nm, more preferably 50 nm to 300 nm inclusive from the surface of the single crystal semiconductor substrate 1101 (to be exact, from the surface of the first semiconductor layer 1103). By forming the fragile layer 1104 at a shallower depth, the single crystal semiconductor substrate after the separation can be thick; therefore, the number of times of reusing the single crystal semiconductor substrate can be increased.

The aforementioned ion irradiation can be performed with the use of an ion doping apparatus or an ion implantation apparatus. Since mass separation is not performed generally in an ion doping apparatus, even when the single crystal semiconductor substrate 1101 is enlarged, the entire surface of the single crystal semiconductor substrate 1101 can be evenly irradiated with ions. In order to increase the thickness of the separated single crystal semiconductor layer in the case of forming the fragile layer 1104 in the single crystal semiconductor substrate 1101 by ion irradiation, the acceleration voltage of an ion doping apparatus or an ion implantation apparatus may be increased.

Note that an ion implantation apparatus refers to an apparatus in which ions produced from a source gas are mass-separated and delivered to an object, so that an element of the ion is added to the object. Further, an ion doping apparatus refers to an apparatus in which ions produced from a source gas are delivered to an object without mass separation, so that an element of the ion is added to the object.

After the fragile layer 1104 is formed, the protective layer 1102 is removed and a conductive film 1105 which serves as one electrode is formed over the first semiconductor layer 1103.

Here, it is preferable that the conductive film 1105 can withstand heat treatment in a step performed later. For example, titanium, molybdenum, tungsten, tantalum, chromium, nickel, or the like can be used for the conductive film 1105. Further, a stack structure of any of the above metal materials and a nitride thereof may be employed. For example, a stack structure of a titanium nitride layer and a titanium layer, a stack structure of a tantalum nitride layer and a tantalum layer, a stack structure of a tungsten nitride layer and a tungsten layer, and the like can be used. In the case of the stack structure including a nitride as described above, the nitride is preferably formed in contact with the first semiconductor layer 1103. By the formation of the nitride, the conductive film 1105 and the first semiconductor layer 1103 can be firmly attached to each other. Note that the conductive film 1105 can be formed by an evaporation method or a sputtering method.

Next, an insulating layer 1106 is formed over the conductive film 1105 (see FIG. 9D). The insulating layer 1106 may have a single-layer structure or a stack structure of two or more layers. In any case, the surface of the insulating layer 1106 is preferably highly smooth. In addition, the outermost surface thereof is desirably hydrophilic. For example, a silicon oxide layer, a silicon nitride layer, a silicon oxynitride layer, a silicon nitride oxide layer, or the like can be formed as the insulating layer 1106. As a method for forming the insulating layer 1106, a CVD method such as a plasma CVD method, a photo CVD method, or a thermal CVD method can be employed. In particular, the employment of a plasma CVD method makes it possible to form the insulating layer 1106 which is smooth and has an average surface roughness (Rₐ) of less than or equal to 0.5 nm (preferably less than or equal to 0.3 nm).

Note that as the insulating layer 1106, in particular, a silicon oxide layer formed by a chemical vapor deposition method using organosilane is preferably used. For organosilane, tetraethoxysilane (TEOS: Si(OC₂H₅)₄), trimethylsilane (TMS: (CH₃)₃SiH), tetramethylcyclotetrasiloxane (TMCTS), octamethylcyclotetrasiloxane (OMCTS), hexamethyldisilazane (HMDS), triethoxysilene (SiH(OC₂H₅)₃), tris(dimethylamino)silane (SiH(N(CH₃)₂)₃), or the like can be used. Needless to say, silicon oxide, silicon oxynitride, silicon nitride, silicon nitride oxide, or the like may be formed using inorganic silane such as monosilane, disilane, or trisilane.

Further, in the case where the insulating layer 1106 has a stacked-layer structure, it preferably includes a silicon insulating layer containing nitrogen, such as a silicon nitride layer or a silicon nitride oxide layer. In this manner, the semiconductor can be prevented from being contaminated by alkali metal or alkaline earth metal from the supporting substrate.

Note that in the case where the conductive film 1105 has a surface with an appropriate smoothness, specifically, in the case where the conductive film 1105 has a surface with an average surface roughness (Rₐ) of less than or equal to 0.5 nm (preferably, less than or equal to 0.3 nm), bonding can be performed without formation of the insulating layer 1106 in some cases. In that case, the insulating layer 1106 do not need to be formed.

Next, pressure is applied to a surface of the insulating layer 1106 and a surface of a supporting substrate 1107 which are closely attached to each other, whereby the supporting substrate 1107 and the stacked-layer structure over the single crystal semiconductor substrate 1101 are bonded to each other (see FIG. 9E).

Before the above bonding, the surfaces to be bonded (here, the surface of the insulating layer 1106 and the surface of the supporting substrate 1107) are cleaned sufficiently. This is because possibility of bonding failure would increase when the surfaces to be bonded include microscopic dust or the like. Note that in order to reduce bonding failure, the surfaces to be bonded may be activated in advance. For example, one or both of the surfaces to be bonded are irradiated with an atomic beam or an ion beam so that the surfaces to be bonded can be activated. Alternatively, the surfaces to be bonded may be activated by plasma treatment, chemical treatment, or the like. Such activation of the surfaces to be bonded enables favorable bonding even at a temperature of less than or equal to 400° C.

Note that a structure may be employed in which a silicon insulating layer containing nitrogen, such as a silicon nitride layer or a silicon nitride oxide layer, is formed over the supporting substrate 1107 and closely attached to the insulating layer 1106. Also in that case, the semiconductor can be prevented from being contaminated by alkali metal or alkaline earth metal from the supporting substrate 1107.

Next, heat treatment is performed to strengthen the bonding. The temperature of the heat treatment should be set so that separation is not promoted at the fragile layer 1104. For example, a temperature of less than 400° C., more preferably less than or equal to 300° C. can be employed. There is no particular limitation on heat treatment time, and an optimal condition may be set as appropriate in accordance with a relationship between processing speed and bonding strength. For example, heat treatment at about 200° C. for about two hours can be employed. Here, local heat treatment can also be performed by irradiating only a region to be bonded with microwaves. Note that, in the case where there is no problem with bonding strength, the aforementioned heat treatment may be omitted.

Next, the single crystal semiconductor substrate 1101 is separated at the fragile layer 1104 into a separation substrate 1108 and a second semiconductor layer 1109 formed of a single crystal semiconductor (see FIG. 9F). The separation of the single crystal semiconductor substrate 1101 is performed by heat treatment. The temperature of the heat treatment can be set in accordance with the upper temperature limit of the supporting substrate 1107. For example, in the case where a glass substrate is used as the supporting substrate 1107, heat treatment is preferably performed at a temperature of 400° C. to 650° C. inclusive. Note that heat treatment may also be performed at a temperature of 400° C. to 700° C. inclusive as long as being performed for a short time. Needless to say, in the case where the upper temperature limit of the glass substrate is higher than 700° C., the temperature of the heat treatment may be set to greater than 700° C.

By the above-described heat treatment, the volume of microvoids formed in the fragile layer 1104 is changed, and then the fragile layer 1104 is cracked. As a result, the single crystal semiconductor substrate 1101 is separated along the fragile layer 1104. Since the insulating layer 1106 is bonded to the supporting substrate 1107, the second semiconductor layer 1109 which is formed of a single crystal semiconductor separated from the single crystal semiconductor substrate 1101 remains over the supporting substrate 1107. Further, since the interface for bonding the insulating layer 1106 to the supporting substrate 1107 is heated by this heat treatment, a covalent bond is formed at the interface for bonding, so that the bonding force between the supporting substrate 1107 and the insulating layer 1106 is further improved.

Note that the total thickness of the second semiconductor layer 1109 and the first semiconductor layer 1103 substantially corresponds to the depth at which the fragile layer 1104 is formed.

When the single crystal semiconductor substrate 1101 is separated at the fragile layer 1104, the separation surface (division surface) of the second semiconductor layer 1109 is uneven in some cases. Crystallinity and planarity of such a surface are damaged due to ions in some cases. Thus, it is preferable that crystallinity and planarity of the surface be recovered so that the second semiconductor layer 1109 can function as a seed layer for epitaxial growth. For example, crystallinity may be recovered by laser treatment or a damaged layer may be removed by etching, and a process for making the surface smooth again may be carried out. Note that at this time, heat treatment is conducted in combination with the laser treatment, which can lead to crystallinity recovery or damage repairing. The heat treatment is preferably conducted at higher temperature and/or for a longer time by using a heating furnace, RTA, or the like, compared to the heat treatment for separating the single crystal semiconductor substrate 1101 at the fragile layer 1104. Needless to say, the heat treatment is conducted at a temperature that does not exceed the strain point of the supporting substrate 1107.

Through the above steps, the second semiconductor layer 1109 formed using a single crystal semiconductor which is fixed to the supporting substrate 1107 can be obtained. Note that the separation substrate 1108 can be reused after a recycling process. The separation substrate 1108 that has been subjected to the recycling process may be reused as a substrate from which a single crystal semiconductor layer is separated (corresponding to the single crystal semiconductor substrate 1101 in this embodiment), or may be used for any other purpose. In the case where the separation substrate 1108 is reused as a substrate from which a single crystal semiconductor layer is separated, a plurality of photoelectric conversion devices can be manufactured from one single crystal semiconductor substrate.

Then, a third semiconductor layer 1110 is formed over the second semiconductor layer 1109, so that a photoelectric conversion layer 1111 including the first semiconductor layer 1103, the second semiconductor layer 1109, and the third semiconductor layer 1110 is formed. Then, after performing processing of the photoelectric conversion layer 1111 into a desired shape and the like, a conductive film 1112 which serves as the other electrode (surface electrode) is formed over the third semiconductor layer 1110 (see FIG. 9G).

In the foregoing manner, the cell including the photoelectric conversion layer formed using a single crystal semiconductor layer can be manufactured. The cell including the photoelectric conversion layer in this embodiment may be attached to a cell including another photoelectric conversion layer using a structure body (a prepreg) in which a fibrous body is impregnated with an organic resin and which is partly conductive as described in the above embodiment, whereby a photoelectric conversion device can be manufactured.

Since single crystal silicon which is a typical example of a single crystal semiconductor is an indirect transition semiconductor, its light absorption coefficient is lower than that of amorphous silicon which is a direct transition semiconductor. Accordingly, a photoelectric conversion layer using single crystal silicon should be several or more times as thick as a photoelectric conversion layer using amorphous silicon in order to absorb sufficient sunlight.

The second semiconductor layer 1109 formed using a single crystal semiconductor is thickened as follows. For example, after a non-single-crystal semiconductor layer is formed so as to cover and fill depressions of the second semiconductor layer 1109, heat treatment is performed, so that the non-single-crystal semiconductor layer is grown using the second semiconductor layer 1109 as a seed layer by solid phase epitaxy. Alternatively, the non-single-crystal semiconductor layer is grown by vapor phase epitaxy by a plasma CVD method or the like. Heat treatment for solid phase epitaxy can be conducted with a heat treatment apparatus such as an RTA apparatus, a furnace, or a high-frequency generation apparatus.

Note that the conductive film 1112 can be formed by a sputtering method or a vacuum evaporation method. Further, the conductive film 1112 is preferably formed using a material that transmits light sufficiently. Examples of the above material include indium tin oxide (ITO), indium tin oxide containing silicon oxide (ITSO), organic indium, organic tin, zinc oxide (ZnO), indium oxide containing zinc oxide (indium zinc oxide (IZO)), ZnO doped with gallium (Ga), tin oxide (SnO₂), indium oxide containing tungsten oxide, indium zinc oxide containing tungsten oxide, indium oxide containing titanium oxide, and indium tin oxide containing titanium oxide. In addition, as the conductive material having a light-transmitting property, a conductive high molecular material (also referred to as conductive polymer) can be used. As the conductive high molecular material, is electron conjugated conductive polymer can be used. For example, polyaniline and/or a derivative thereof, polypyrrole and/or a derivative thereof, polythiophene and/or a derivative thereof, a copolymer of two or more kinds of those materials, and the like can be given.

Note that this embodiment can be combined with any of the other embodiments as appropriate.

### Embodiment 5

In this embodiment, an example of a method for forming a cell including a photoelectric conversion layer formed using a single crystal semiconductor substrate will be described. Note that description in this embodiment will be made on manufacture of a cell disposed on the side opposite to the light incident side (a bottom cell). In the case where a cell manufactured by a manufacturing method described in this embodiment is manufactured as a cell disposed on the light incident side (a top cell), the stacking order of electrodes and layers included in a photoelectric conversion layer may be changed as appropriate.

A photoelectric conversion layer formed using a single crystal semiconductor substrate, for example, has a semiconductor junction in the single crystal semiconductor substrate. Over a conductive film serving as one of electrodes (a back electrode), the photoelectric conversion layer in which a first semiconductor layer, a second semiconductor layer, and a third semiconductor layer are stacked is formed. Then, a surface of the photoelectric conversion layer is made to have a texture structure (an uneven structure) and an electrode is formed over the photoelectric conversion layer, whereby a cell manufactured using the single crystal semiconductor substrate can be obtained.

Note that the first semiconductor layer and the third semiconductor layer are formed so that an impurity element imparting a first conductivity type (e.g., n-type conductivity) is introduced into one of the first semiconductor layer and the third semiconductor layer and an impurity element imparting a second conductivity type (e.g., p-type conductivity) is introduced into the other. Further, the second semiconductor layer is preferably an intrinsic semiconductor layer or a layer to which either the impurity element imparting the first conductivity type or the impurity element imparting the second conductivity type is introduced. Although the example in which three semiconductor layers are stacked to form the photoelectric conversion layer is described in this embodiment, plural semiconductor layers may be stacked to form other junction such as a p-n junction.

In this embodiment, the first semiconductor layer, the second semiconductor layer, and the third semiconductor layer are illustrated with the same number in a cross-sectional view of a photoelectric conversion layer which is illustrated as an example. However, in the case where the conductivity type of the second semiconductor layer is either p-type or n-type, a p-n junction is formed either between the first semiconductor layer and the second semiconductor layer or between the second semiconductor layer and the third semiconductor layer. The area of the p-n junction is preferably large so that carriers induced by light can move to the p-n junction without being recombined. Thus, the number and shape of the first semiconductor layer and the number and shape of the third semiconductor layer do not need to be the same. In addition, also in the case where the conductivity type of the second semiconductor layer is i-type, the area of the p-i junction is preferably large because the lifetime of a hole is shorter than that of an electron. Thus, the number and shape of the first semiconductor layer and the number and shape of the third semiconductor layer do not need to be the same as in the case of the p-n junction.

Note that a “single crystal semiconductor” here refers to a semiconductor in which crystal faces and crystal axes are aligned, and constituent atoms or molecules are aligned in a spatially ordered manner. Note that a single crystal semiconductor also includes a semiconductor having irregularity such as a semiconductor having a lattice defect in which the alignment of atoms or molecules is partly disordered or a semiconductor having intended or unintended lattice distortion.

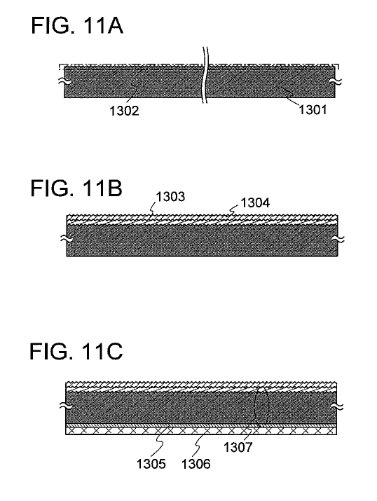

FIGS. 11A to 11C illustrate an example of a manufacturing process of a cell including a photoelectric conversion layer of this embodiment.

First, one surface of a single crystal semiconductor substrate 1301 to which a first conductivity type is imparted is processed by etching or the like, whereby a texture structure (an uneven structure) 1302 (see FIG. 11A) is formed. When the surface of the single crystal semiconductor substrate 1301 is made to have the texture structure, light can be diffusely reflected. Thus, light which is incident on a semiconductor junction to be formed later can be efficiently converted into electric energy.

Note that the conductivity type of the single crystal semiconductor substrate 1301 is not particularly limited to the first conductivity type (e.g., p-type). It is preferable that the concentration of an impurity element which is introduced into the single crystal semiconductor substrate 1301 be lower than the concentration of an impurity element imparting a conductivity type which is introduced into a first semiconductor layer and a third semiconductor layer which are formed later.

As the single crystal semiconductor substrate 1301, a semiconductor wafer of silicon, germanium, or the like; a compound semiconductor wafer of gallium arsenide, indium phosphide, or the like; or the like can be used. In particular, a single crystal silicon wafer is preferably used.

Many of single crystal silicon wafers on the market are circular in shape. In the case where such a circular wafer is used, the circular wafer may be processed to be rectangular or polygonal in shape as described in the above embodiment with reference to FIGS. 10A to 10C.

Next, a first semiconductor layer 1303 is formed over the texture structure 1302 of the single crystal semiconductor substrate 1301. The first semiconductor layer 1303 may be formed in such a manner that an impurity element imparting a second conductivity type is introduced into the single crystal semiconductor substrate 1301 by a thermal diffusion method or the like, or may be formed over the single crystal semiconductor substrate 1301 in which the texture structure 1302 is formed. Note that an element belonging to Group 15 of the periodic table, for example, phosphorus may be used as the impurity element imparting the second conductivity type.

Next, a conductive film 1304 serving as a surface electrode is formed over the first semiconductor layer 1303 (see FIG. 11B). Note that another film such as an antireflection film may be formed between the first semiconductor layer 1303 and the conductive film 1304.

Note that the conductive film 1304 can be formed by a sputtering method or a vacuum evaporation method. Further, the conductive film 1304 is preferably formed using a material which sufficiently transmits light. The conductive film 1304 can be formed using, for example, indium tin oxide (ITO), indium tin oxide containing silicon oxide (ITSO), organoindium, organotin, zinc oxide (ZnO), indium oxide containing zinc oxide (indium zinc oxide (IZO)), ZnO doped with gallium (Ga), tin oxide (SnO₂), indium oxide containing tungsten oxide, indium zinc oxide containing tungsten oxide, indium oxide containing titanium oxide, or indium tin oxide containing titanium oxide. As a conductive material with a light-transmitting property, a conductive high molecular material (also referred to as a conductive polymer) can be used. As the conductive high molecular material, a π electron conjugated conductive high molecule can be used. For example, polyaniline and/or a derivative thereof, polypyrrole and/or a derivative thereof, polythiophene and/or a derivative thereof, and a copolymer of two or more kinds of those materials can be given.

The conductive film 1304 may be formed by application and printing of a solvent containing a metal such as a silver paste by a printing method such as a screen printing method. A surface on which the conductive film 1304 is formed serves as a light-receiving surface. For that reason, the conductive film is not formed on the entire surface but is formed in a net-like shape so that light can be sufficiently transmitted.

Next, a third semiconductor layer 1305 and a conductive film 1306 serving as a back electrode are formed on a surface opposite to a surface on the side where the texture structure 1302 of the single crystal semiconductor substrate 1301 and the conductive film 1304 are provided (see FIG. 11C). The third semiconductor layer 1305 may be formed in such a manner that an impurity element imparting a first conductivity type is introduced into the single crystal semiconductor substrate 1301 by a thermal diffusion method or the like or may be formed to be in contact with the single crystal semiconductor substrate 1301. As the impurity element imparting the first conductivity type, for example, an element belonging to Group 13 of the periodic table, such as boron, may be used.

Further, a metal film with high light reflectivity is preferably used as the conductive film 1306. For example, aluminum, silver, titanium, tantalum, or the like can be used. The conductive film 1306 can be formed by an evaporation method or a sputtering method. The conductive film 1306 may be formed of plural layers. For example, a buffer layer or the like for improving adhesion between the conductive film 1306 and the third semiconductor layer 1305 may be formed of a metal film, a metal oxide film, a metal nitride film, or the like, and those layers may be stacked. The conductive film 1306 may be formed of a stacked layer of a metal film with high light reflectivity and a metal film with low light reflectivity.

Through the above steps, a photoelectric conversion layer 1307 which includes the first semiconductor layer 1303, the single crystal semiconductor substrate 1301 serving as the second semiconductor layer, and the third semiconductor layer 1305 and which is interposed between the conductive film 1304 and the conductive film 1306 can be obtained, and a cell including the photoelectric conversion layer formed using the single crystal semiconductor substrate can be manufactured. In this embodiment, when the cell including the photoelectric conversion layer is bonded to a cell including another photoelectric conversion layer with a structure body (prepreg) in which a fibrous body is impregnated with an organic resin as described in the above embodiment, a photoelectric conversion device can be manufactured.

Note that this embodiment can be combined with any of the other embodiments as appropriate.

### Embodiment 6

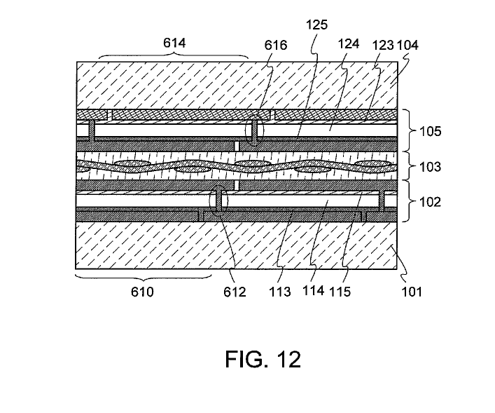

In this embodiment, an example of a photoelectric conversion device in which cells are connected in series will be described (see FIG. 12).

A photoelectric conversion device illustrated in FIG. 12 includes the cell 102 in which photoelectric conversion layers are connected in series over the substrate 101 and the cell 105 in which photoelectric conversion layers are connected in series over the substrate 104.

Specifically, a first conductive layer and a second conductive layer are electrically connected to each other through a conduction portion 612 provided in part of the photoelectric conversion layer, whereby the photoelectric conversion layer in a photoelectric conversion region 610 and the photoelectric conversion layer in a photoelectric conversion region adjacent to the photoelectric conversion region 610 are connected in series. Further, a first conductive layer and a second conductive layer are electrically connected to each other through a conduction portion 616 provided in part of the photoelectric conversion layer, whereby the photoelectric conversion layer in a photoelectric conversion region 614 and the photoelectric conversion layer in a photoelectric conversion region adjacent to the photoelectric conversion region 614 are connected in series.

Although there is no particular limitation on the manufacturing method, for example, a method described below can be employed. A first conductive layer with a predetermined pattern is formed over the substrate 101, a photoelectric conversion layer is formed, the photoelectric conversion layer is patterned to form a contact hole reaching the first conductive layer, a second conductive layer is formed so as to cover the photoelectric conversion layer, and at least the second conductive layer is patterned, whereby the cell 102 is formed over the substrate 101. The cell 105 is formed over the substrate 104 by a method similar to the above-described method. The cell 102 and the cell 105 are bonded to each other with the structure body 103, whereby a photoelectric conversion device is completed. Note that the aforementioned embodiment may be referred to for detailed description of each step.

The above described structure enables a large number of photoelectric conversion layers to be connected in series. In other words, a photoelectric conversion device capable of supplying sufficient voltage even for use requiring a large amount of voltage can be provided.

Note that this embodiment can be combined with any of the other embodiments as appropriate.

### Embodiment 7

In this embodiment, an example of an apparatus that can be used for manufacture of a photoelectric conversion device will be described with reference to drawings.

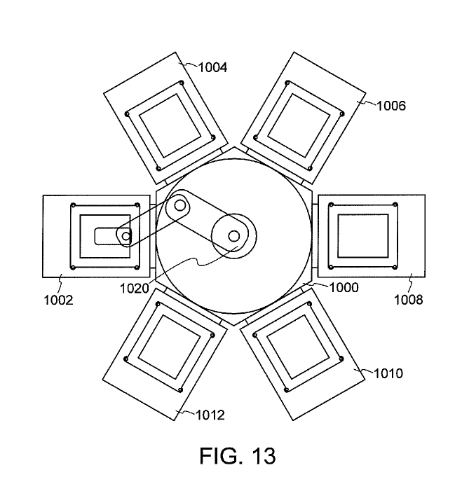

FIG. 13 illustrates an example of an apparatus that can be used for manufacture of a photoelectric conversion device, especially, a photoelectric conversion layer. The apparatus illustrated in FIG. 13 is equipped with a transfer chamber 1000, a load/unload chamber 1002, a first deposition chamber 1004, a second deposition chamber 1006, a third deposition chamber 1008, a fourth deposition chamber 1010, a fifth deposition chamber 1012, and a transfer robot 1020.

A substrate is transferred between the load/unload chamber 1002 and the deposition chambers by the transfer robot 1020 provided in the transfer chamber 1000. In each deposition chamber, a semiconductor layer included in a photoelectric conversion layer is formed. Hereinafter, an example of a deposition process of a photoelectric conversion layer with the apparatus is described.

First, a substrate introduced into the load/unload chamber 1002 is transferred to the first deposition chamber 1004 by the transfer robot 1020. It is desirable that a conductive film serving as an electrode or a wiring be formed over the substrate in advance. The material, shape (pattern), and the like of the conductive film can be changed as appropriate in accordance with required optical characteristics or electrical characteristics. Note that the case where a glass substrate is used as the substrate, a conductive film with a light-transmitting property is formed as the conductive film, and light enters a photoelectric conversion layer from the conductive film is described here as an example.

In the first deposition chamber 1004, a first semiconductor layer which is to be in contact with the conductive film is formed. Here, the case where a semiconductor layer (a p layer) to which an impurity element imparting p-type conductivity is added is formed as the first semiconductor layer is described. However, an embodiment of the disclosed invention is not limited thereto. A semiconductor layer (an n layer) to which an impurity element imparting n-type conductivity is added may be formed. A CVD method and the like can be given as a typical example of a deposition method; however, an embodiment of the disclosed invention is not limited thereto. The first semiconductor layer may be formed by, for example, a sputtering method. Note that in the case where the first semiconductor layer is formed by a CVD method, the deposition chamber can also be called a “CVD chamber”.

Next, the substrate over which the first semiconductor layer is formed is transferred to any of the second deposition chamber 1006, the third deposition chamber 1008, or the fourth deposition chamber 1010. In the second deposition chamber 1006, the third deposition chamber 1008, or the fourth deposition chamber 1010, a second semiconductor layer (an i layer) to which an impurity element imparting conductivity is not added is formed so as to be in contact with the first semiconductor layer.

Three deposition chambers of the second deposition chamber 1006, the third deposition chamber 1008, and the fourth deposition chamber 1010 are prepared for forming the second semiconductor layer because the second semiconductor layer needs to be formed to have a larger thickness than the first semiconductor layer. In the case where the second semiconductor layer is formed to have a larger thickness than the first semiconductor layer, the time needed for the formation process of the second semiconductor layer is longer than that needed for the formation process of the first semiconductor layer in view of the deposition rates of the first semiconductor layer and the second semiconductor layer. Therefore, in the case where the second semiconductor layer is formed in only one deposition chamber, the deposition process of the second semiconductor layer is a rate-controlling factor. For the above reason, the apparatus illustrated in FIG. 13 has a structure in which three deposition chambers are provided for formation of the second semiconductor layer. Note that the structure of the apparatus which can be used for formation of the photoelectric conversion layer is not limited thereto. Although a CVD method or the like can be used for forming the second semiconductor layer similarly to the case of the first semiconductor layer, an embodiment of the disclosed invention is not limited thereto.

Next, the substrate over which the second semiconductor layer is formed is transferred to the fifth deposition chamber 1012. In the fifth deposition chamber 1012, a third semiconductor layer to which an impurity element imparting a different conductivity type from the first semiconductor layer is added is formed so as to be in contact with the second semiconductor layer. Here, the case where a semiconductor layer (an n layer) to which an impurity element imparting n-type conductivity is added is formed as the third semiconductor layer is described. However, an embodiment of the disclosed invention is not limited thereto. Although a CVD method or the like can be used for forming the third semiconductor layer similarly to the case of the first semiconductor layer, an embodiment of the disclosed invention is not limited thereto.

Through the above steps, a photoelectric conversion layer having a structure in which the first semiconductor layer, the second semiconductor layer, and the third semiconductor layer are stacked can be formed over the conductive film.

The apparatus equipped with the load/unload chamber 1002; the first deposition chamber 1004 for forming the first semiconductor layer; the second deposition chamber 1006, the third deposition chamber 1008, and the fourth deposition chamber 1010 for forming the second semiconductor layer; and the fifth deposition chamber 1012 for forming the third semiconductor layer is described with reference to FIG. 13. However, the structure of the apparatus that can be used for manufacture of the photoelectric conversion device of the disclosed invention is not limited to the structure. For example, the fourth deposition chamber 1010 may be used for formation of the third semiconductor layer.

The example of the apparatus equipped with six chambers is described with reference to FIG. 13; however, the apparatus that can be used for manufacture of the photoelectric conversion device of the disclosed invention is not limited to the structure. The apparatus may be equipped with, for example, a deposition chamber for forming a conductive film, a surface treatment chamber for performing various kinds of surface treatment, an analysis chamber for analyzing film quality, or the like.

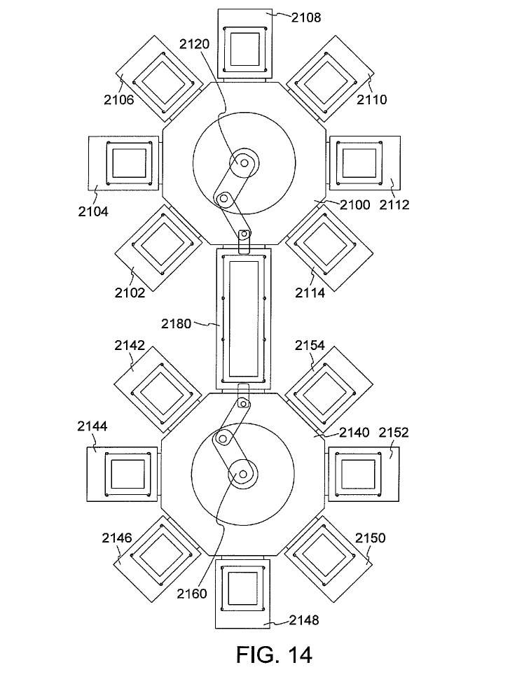

FIG. 14 illustrates an example of an apparatus that can be used for formation of a structure in which a plurality of photoelectric conversion layers are stacked. The apparatus illustrated in FIG. 14 is equipped with a transfer chamber 2100, an analysis chamber 2102, a surface treatment chamber 2104, a first deposition chamber 2106, a load chamber 2108, a second deposition chamber 2110, a third deposition chamber 2112, a fourth deposition chamber 2114, a transfer robot 2120, a transfer chamber 2140, a first deposition chamber 2142, a second deposition chamber 2144, a third deposition chamber 2146, an unload chamber 2148, a fourth deposition chamber 2150, a fifth deposition chamber 2152, a sixth deposition chamber 2154, and a transfer robot 2160. The apparatus has a structure in which the transfer chamber 2100 and the transfer chamber 2140 are connected to each other with a connection chamber 2180.

A substrate is transferred between the load chamber 2108, the analysis chamber 2102, the surface treatment chamber 2104, and the deposition chambers around the transfer chamber 2100 by the transfer robot 2120 provided in the transfer chamber 2100. In addition, a substrate is transferred between the unload chamber 2148 and the deposition chambers around the transfer chamber 2140 by the transfer robot 2160 provided in the transfer chamber 2140. In the deposition chambers, semiconductor layers included in a photoelectric conversion layer, a conductive film of a photoelectric conversion device, and the like are formed. Hereinafter, an example of a deposition process of the photoelectric conversion layer with the apparatus is described.

First, a substrate introduced into the load chamber 2108 is transferred to the first deposition chamber 2106 by the transfer robot 2120. A conductive film serving as an electrode or a wiring is formed over the substrate in the first deposition chamber 2106. The material, shape (pattern), and the like of the conductive film can be changed as appropriate in accordance with required optical characteristics or electrical characteristics. A sputtering method can typically be used as a deposition method of the conductive film; however, an embodiment of the disclosed invention is not limited thereto. For example, an evaporation method may be used. In the case where the conductive film is formed by a sputtering method, the deposition chamber can also be called a “sputtering chamber”. Note that the case where a glass substrate is used as the substrate, a conductive film with a light-transmitting property is formed as the conductive film, and light enters a photoelectric conversion layer from the conductive film is described here as an example.

Next, the substrate over which the conductive film is formed is transferred to the surface treatment chamber 2104. In the surface treatment chamber 2104, treatment for making a surface of the conductive film have an uneven shape (a texture structure) is performed. This realizes light confinement in the photoelectric conversion layer; therefore, photoelectric conversion efficiency of the photoelectric conversion device can be increased. Etching treatment can be given as an example of a formation method of the uneven shape; however, an embodiment of the disclosed invention is not limited thereto.

Next, the substrate is transferred to the second deposition chamber 2110. In the second deposition chamber 2110, a first semiconductor layer of a first photoelectric conversion layer which is to be in contact with the conductive film is formed. Here, the case where a semiconductor layer (a p layer) to which an impurity element imparting p-type conductivity is added is formed as the first semiconductor layer is described. However, an embodiment of the disclosed invention is not limited thereto. A semiconductor layer (an n layer) to which an impurity element imparting n-type conductivity is added may be formed. A CVD method or the like can be given as a typical example of a deposition method; however, an embodiment of the disclosed invention is not limited thereto. The first semiconductor layer may be formed by, for example, a sputtering method.

Next, the substrate over which the first semiconductor layer is formed is transferred to the third deposition chamber 2112. In the third deposition chamber 2112, a second semiconductor layer (an i layer) to which an impurity element imparting conductivity is not added is formed so as to be in contact with the first semiconductor layer. A CVD method and the like can be given as an example of a formation method of the second semiconductor layer similarly to the case of the first semiconductor layer. However, an embodiment of the disclosed invention is not limited thereto.

Next, the substrate over which the second semiconductor layer is formed is transferred to the fourth deposition chamber 2114. In the fourth deposition chamber 2114, a third semiconductor layer to which an impurity element imparting a different conductivity type from the first semiconductor layer is added is formed so as to be in contact with the second semiconductor layer. Here, the case where a semiconductor layer (an n layer) to which an impurity element imparting n-type conductivity is added is formed as the third semiconductor layer is described. However, an embodiment of the disclosed invention is not limited thereto. Although a CVD method or the like can be used for formation of the third semiconductor layer similarly to the case of the first semiconductor layer, an embodiment of the disclosed invention is not limited thereto.

Through the above steps, a first electric conversion layer having a structure in which the first semiconductor layer, the second semiconductor layer, and the third semiconductor layer are stacked can be formed over the conductive film.

Next, the substrate over which the first photoelectric conversion layer is formed is again transferred to the first deposition chamber 2106. In the first deposition chamber 2106, an intermediate layer with conductivity is formed over the first photoelectric conversion layer. Although the material, shape (pattern), and the like of the intermediate layer can be changed as appropriate in accordance with required optical characteristics or electrical characteristics, the intermediate layer desirably has a similar structure to the conductive film in view of the manufacturing process.

Next, the substrate over which the intermediate layer is formed is delivered to the transfer robot 2160 through the connection chamber 2180. The transfer robot 2160 transfers the substrate to the first deposition chamber 2142. In the first deposition chamber 2142, a first semiconductor layer of a second photoelectric conversion layer which is to be in contact with the intermediate layer is formed. Here, the case where a semiconductor layer (a p layer) to which an impurity element imparting p-type conductivity is added is formed as the first semiconductor layer is described. However, an embodiment of the disclosed invention is not limited thereto. Although a CVD method or the like can be given as a typical example of a deposition method, an embodiment of the disclosed invention is not limited thereto.

Next, the substrate over which the first semiconductor layer is formed is transferred to any of the fourth deposition chamber 2150, the fifth deposition chamber 2152, and the sixth deposition chamber 2154. In the fourth deposition chamber 2150, the fifth deposition chamber 2152, and the sixth deposition chamber 2154, a second semiconductor layer (an i layer) to which an impurity element imparting conductivity is not added is formed so as to be in contact with the first semiconductor layer. Although a CVD method or the like can be given as an example of a deposition method similarly to the case of the first semiconductor layer, an embodiment of the disclosed invention is not limited thereto.

Three deposition chambers of the fourth deposition chamber 2150, the fifth deposition chamber 2152, and the sixth deposition chamber 2154 are prepared for formation of the second semiconductor layer for the reason similar to that for the apparatus illustrated in FIG. 13. In other words, the second semiconductor layer (the i layer) in the second photoelectric conversion layer is formed to have a larger thickness than the second semiconductor layer (the i layer) in the first photoelectric conversion layer. Note that the structure of the apparatus that can be used for formation of the photoelectric conversion layer is not limited thereto. Although a CVD method or the like can be used for formation of the second semiconductor layer similarly to the case of the first semiconductor layer, an embodiment of the disclosed invention is not limited thereto.

Next, the substrate over which the second semiconductor layer is formed is transferred to the second deposition chamber 2144. In the second deposition chamber 2144, a third semiconductor layer to which an impurity element imparting a different conductivity type from the first semiconductor layer is added is formed so as to be in contact with the second semiconductor layer. Here, the case where a semiconductor layer (an n layer) to which an impurity element imparting n-type conductivity is added is formed as the third semiconductor layer is described. However, an embodiment of the disclosed invention is not limited thereto. Although a CVD method or the like can be used for formation of the third semiconductor layer similarly to the case of the first semiconductor layer, an embodiment of the disclosed invention is not limited thereto.

Through the above steps, the second photoelectric conversion layer having a structure in which the first semiconductor layer, the second semiconductor layer, and the third semiconductor layer are stacked can be formed over the intermediate layer.

Next, the substrate over which the second photoelectric conversion layer is formed is transferred to the third deposition chamber 2146. In the third deposition chamber 2146, a conductive film serving as an electrode or a wiring is formed over the second photoelectric conversion layer. The material, shape (pattern), and the like of the conductive film can be changed as appropriate in accordance with required optical characteristics or electrical characteristics. A sputtering method can typically be used as a deposition method of the conductive film; however, an embodiment of the disclosed invention is not limited thereto. For example, an evaporation method may be used. In the case where the conductive film is formed by a sputtering method, the deposition chamber can also be called a “sputtering chamber”. Note that, although the case where a conductive film with light reflectivity is formed as the conductive film is described here, an embodiment of the disclosed invention is not limited thereto. For example, a conductive film with a light-transmitting property and a conductive film with light reflectivity may be stacked to form the conductive film.

After that, the substrate is taken out from the unload chamber 2148.

Through the above steps, a photoelectric conversion device having a structure in which the conductive film, the first photoelectric conversion layer, the intermediate layer, the second photoelectric conversion layer, and the conductive film are stacked in that order over the substrate can be manufactured.

Note that the structures of the chambers connected to the transfer chamber 2100 and the transfer chamber 2140 are not limited to the structures illustrated in FIG. 14. The number of chambers can be increased or decreased.

Note that the timing or the number of surface treatment for the conductive films or the like is not limited to that described above. For example, surface treatment may be performed after the formation of the conductive film. Etching treatment for pattern formation, or the like may be performed before or after the formation of each layer.

### Embodiment 8

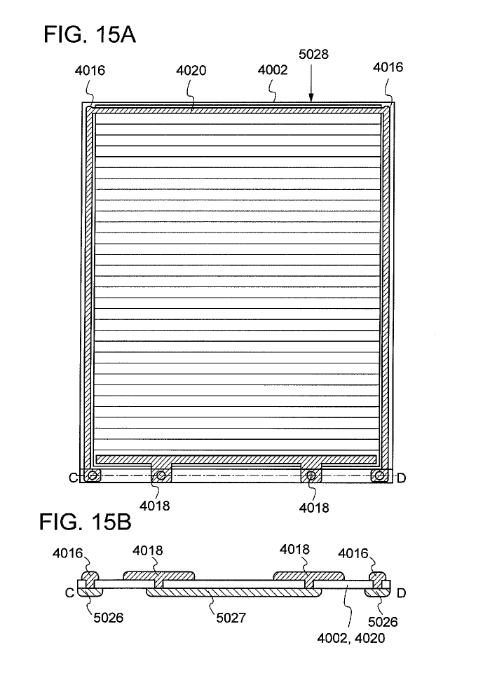

A solar photovoltaic module can be manufactured using the photoelectric conversion device obtained by any of Embodiments 1 to 7 and the like. In this embodiment, an example of a solar photovoltaic module in which the photoelectric conversion device described in Embodiment 1 is used is illustrated in FIG. 15A. A solar photovoltaic module 5028 includes a plurality of unit cells 4020 provided over a supporting substrate 4002. In the unit cell 4020 over the supporting substrate 4002, a first cell interposed between two conductive films, a structure body, and a second cell interposed between two conductive films are stacked from the supporting substrate 4002 side. Further, one of the conductive films of the first cell and one of the conductive films of the second cell are connected to the first electrode 4016, and the other conductive film of the first cell and the other conductive film of the second cell are connected to a second electrode 4018.

Although not particularly illustrated in FIGS. 15A and 15B, one of the conductive films of the first cell and one of the conductive films of the second cell may be connected to each other in advance to be connected to the first electrode 4016. Alternatively, a plurality of first electrodes 4016 are provided and one of the conductive films of the first cell and one of the conductive films of the second cell may be connected to respective first electrodes 4016. In a similar manner, the other conductive film of the first cell and the other conductive film of the second cell may be connected to each other in advance to be connected to the second electrode 4018. Alternatively, a plurality of second electrodes 4018 are provided and the other conductive film of the first cell and the other conductive film of the second cell may be connected to respective second electrodes 4018.

The first electrode 4016 and the second electrode 4018 are formed on one surface side of the supporting substrate 4002 (the side where the unit cell 4020 is formed) and are connected to a back electrode 5026 and a back electrode 5027 which are used for an external terminal connector, respectively, at end portions of the supporting substrate 4002. FIG. 15B is a cross-sectional view taken along the line C-D of FIG. 15A. In FIG. 15B, the first electrode 4016 and the second electrode 4018 are connected to the back electrode 5026 and the back electrode 5027, respectively, through penetration openings of the supporting substrate 4002.

Note that this embodiment can be combined with any of the other embodiments as appropriate.

### Embodiment 9

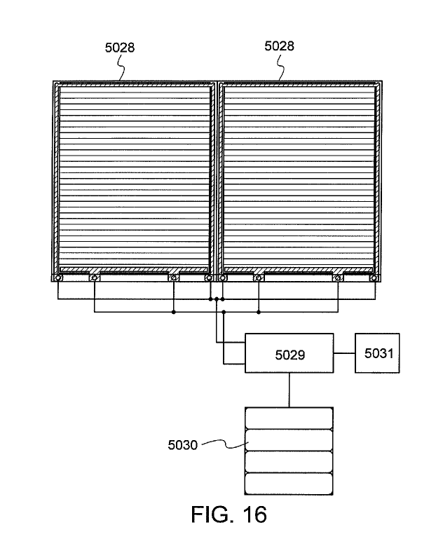

FIG. 16 illustrates an example of a solar photovoltaic system in which the solar photovoltaic module 5028 described in Embodiment 8 is used. A charge control circuit 5029 provided with a DC-DC converter or the like controls electric power supplied from one or a plurality of solar photovoltaic modules 5028 to charge a storage battery 5030. Further, in the case where the storage battery 5030 is sufficiently charged, the charge control circuit 5029 controls electric power supplied from one or a plurality of solar photovoltaic modules 5028 so that the electrode power is directly outputted to a load 5031.

When an electric double layer capacitor is used as the storage battery 5030, the storage battery 5030 does not need chemical reaction in charging; thus, the storage battery 5030 can be charged rapidly. Further, lifetime can be increased by about 8 times and charging and discharging efficiency can be increased by about 1.5 times compared with those of a lead storage battery or the like which uses chemical reaction. The solar photovoltaic system described in this embodiment can be used in various types of loads 5031 which use electric power, such as lighting or an electronic device.

Note that this embodiment can be combined with any of the other embodiments as appropriate.

### Embodiment 10

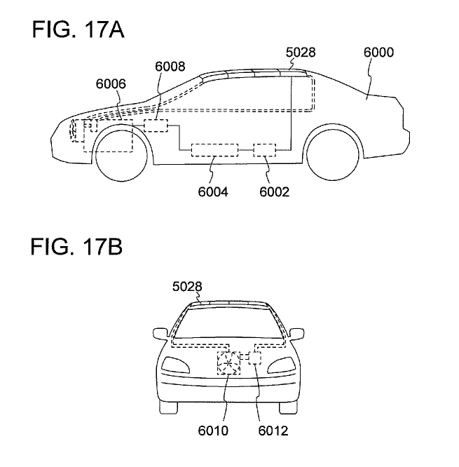

FIGS. 17A and 17B illustrate an example of a vehicle (car) 6000 in which the solar photovoltaic module 5028 described in Embodiment 8 is used for its roof portion. The solar photovoltaic module 5028 is connected to a battery or a capacitor 6004 through a converter 6002. In other words, the battery or the capacitor 6004 is charged with electric power supplied from the solar photovoltaic module 5028. Charge or discharge may be selected in accordance with operation condition of an engine 6006 which is monitored by a monitor 6008.

The photoelectric conversion efficiency of the solar photovoltaic module 5028 tends to be decreased by heat. In order to suppress such a decrease in photoelectric conversion efficiency, liquid for cooling or the like may be circulated in the solar photovoltaic module 5028. For example, cooling water in a radiator 6010 may be circulated by a circulation pump 6012. Needless to say, an embodiment of the disclosed invention is not limited to the structure in which the liquid for cooling is shared by the solar photovoltaic module 5028 and the radiator 6010. In the case where a decrease in photoelectric conversion efficiency is not serious, the liquid does not need to be circulated.

Note that this embodiment can be combined with any of the other embodiments as appropriate.

### Embodiment 11

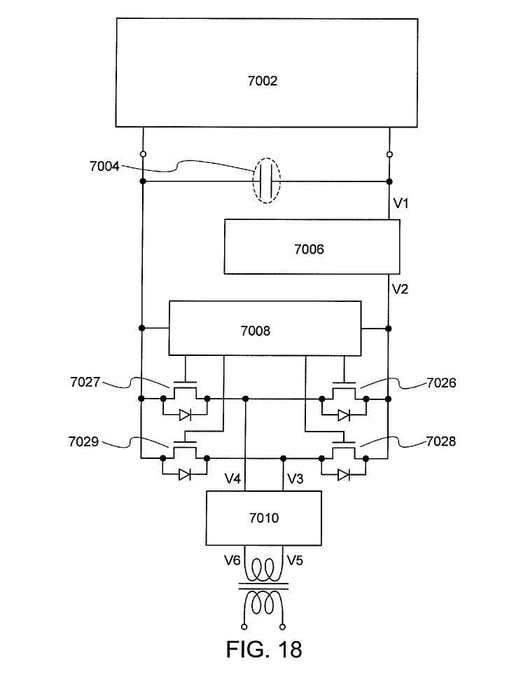

FIG. 18 illustrates one mode of an inverter capable of stably extracting AC power from an output of the photoelectric conversion device of any one of embodiments without using an external power source.

Since the output of the photoelectric conversion device varies depending on the amount of incident light, stable output cannot be obtained in some cases when an output voltage is used without any change. The inverter which is illustrated in FIG. 18 as an example is provided with a capacitor 7004 for stabilization and a switching regulator 7006 to operate so as to produce a stable DC voltage.

For example, a stable DC voltage of 30 V can be produced by the switching regulator 7006 when the output voltage of the photoelectric conversion device 7002 is 10 V to 15 V.

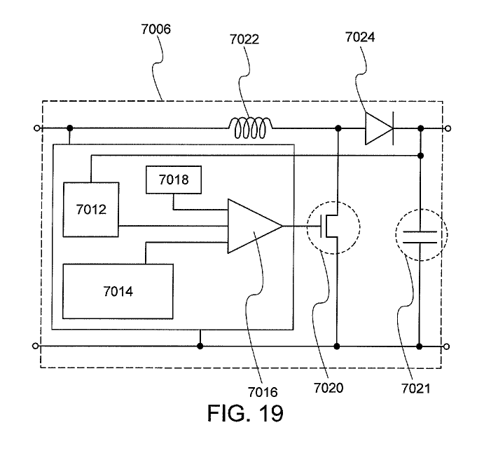

FIG. 19 is a block diagram of the switching regulator 7006. The switching regulator 7006 includes an attenuator 7012, a triangle wave generation circuit 7014, a comparator 7016, a switching transistor 7020, and a smoothing capacitor 7021.

When a signal of the triangle wave generation circuit 7014 is inputted to the comparator 7016, the switching transistor 7020 is turned on, whereby energy is stored in the inductor 7022. Thus, a voltage V2 that is higher than an output voltage V1 of the photoelectric conversion device 7002 is produced at an output of the switching regulator 7006. This voltage returns to the comparator 7016 via the attenuator 7012, and a produced voltage is controlled so as to be equal to a reference voltage 7018.

For example, with a reference voltage of 5 V and adjustment with the attenuator (⅙), the voltage V2 is controlled so as to be 30 V.

A diode 7024 is provided for backflow prevention. The output voltage of the switching regulator 7006 is smoothed by the smoothing capacitor 7021.

In FIG. 18, a pulse width modulation circuit 7008 is operated using the output voltage V2 of the switching regulator 7006. In the pulse width modulation circuit 7008, a pulse width modulation wave can be digitally generated by a microcomputer or may be generated in an analog manner.

Outputs of the pulse width modulation circuit 7008 are inputted to switching transistors 7026 to 7029, whereby pulse width modulation waves V3 and V4 are generated. The pulse width modulation waves V3 and V4 are converted into sine waves through a band pass filter 7010.

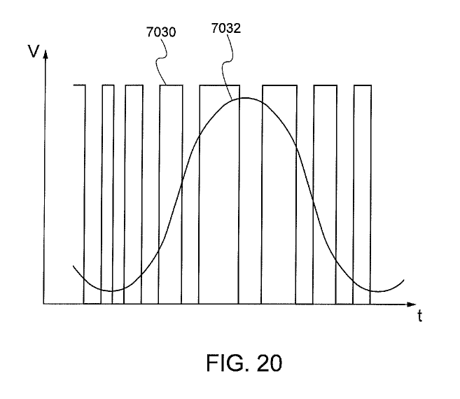

In other words, as illustrated in FIG. 20, a pulse width modulation wave 7030 is a rectangular wave the duty cycle of which is changed in a given cycle, and the pulse width modulation wave 7030 is passed through the band pass filter 7010, so that a sin wave 7032 can be obtained.

As described above, AC power V5 and V6 can be generated using the output of the photoelectric conversion device 7002, without using an external power source.

Note that this embodiment can be combined with any of the other embodiments as appropriate.

### Embodiment 12

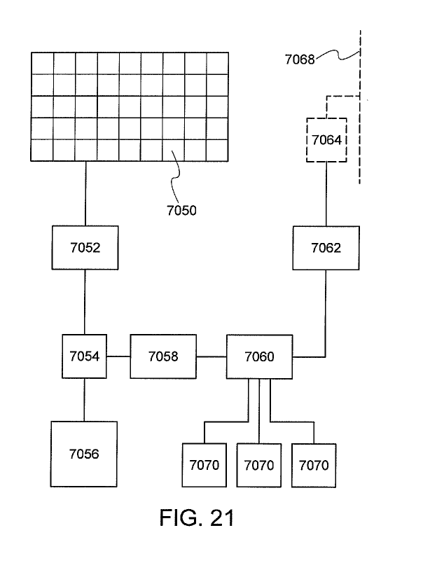

In this embodiment, an example of a photovoltaic system will be described with reference to FIG. 21. A structure in which this photovoltaic system is installed on a house or the like will be described.

This photovoltaic system has a structure in which electric power generated in a photoelectric conversion device 7050 is used for charging of a power storage device 7056, or electric power generated can be consumed as AC power in an inverter 7058. Surplus electric power generated in the photoelectric conversion device 7050 is sold to an electric power company or the like. On the other hand, at night time or at the time of rain when electric power is insufficient, electric power is supplied from an electric grid 7068 to a house or the like.

Consumption of electric power generated in the photoelectric conversion device 7050 and reception of electric power from the electric grid 7068 are switched by a DC switch 7052 connected to the photoelectric conversion device 7050 side and an AC switch 7062 connected to the electric grid 7068 side.

A charge control circuit 7054 controls charging of the power storage device 7056 and controls supply of electric power from the power storage device 7056 to the inverter 7058.

The power storage device 7056 includes a secondary battery such as a lithium-ion battery or a capacitor such as a lithium-ion capacitor. A secondary battery or a capacitor utilizing sodium instead of lithium as an electrode material may be used in such a power storage unit.

AC power outputted from the inverter 7058 is used as electric power for operating various types of electric devices 7070.

Surplus electric power generated in the photoelectric conversion device 7050 is transmitted through the electric grid 7068 to be sold to an electric power company. The AC switch 7062 is provided for selection of connection or disconnection between the electric grid 7068 and a distribution board 7060 through a transformer 7064.

As described above, the photovoltaic system of this embodiment is capable of providing a house or the like having few environmental load with use of the photoelectric conversion device of an embodiment of the disclosed invention.

Note that this embodiment can be combined with any of the other embodiments as appropriate.

### Embodiment 13

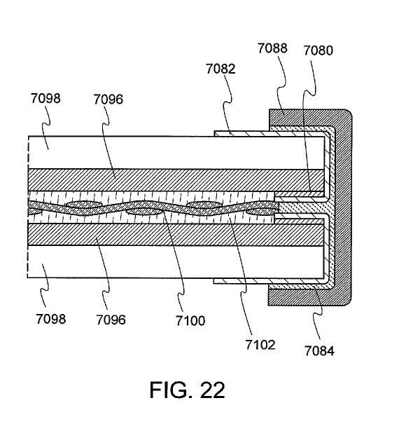

As illustrated in FIG. 22, a frame 7088 is provided in a peripheral portion of a pair of substrates 7098 which overlap so as to interpose a fibrous body 7100 and an organic resin 7102 therebetween with their first surfaces provided with cells 7096 facing inward.

The inside of the frame 7088 is filled with a sealing resin 7084 so that entry of water can be prevented. A conductive member 7080 such as a solder or a conductive paste is provided for a contact portion of a terminal portion of each cell 7096 with a wiring member 7082 so that the bonding strength can be increased. The wiring member 7082 is led from the first surface side of the substrate 7098 to a second surface side inside the frame 7088.

A pair of cells 7096 are bonded so that the substrates 7098 which serve as supporting members of the cells 7096 are provided outside can serve as a two-side sealing member, and a reduction in thickness of a photoelectric conversion device can be achieved while increasing the amount of power generation by 1.5 times, ideally, 2 times.

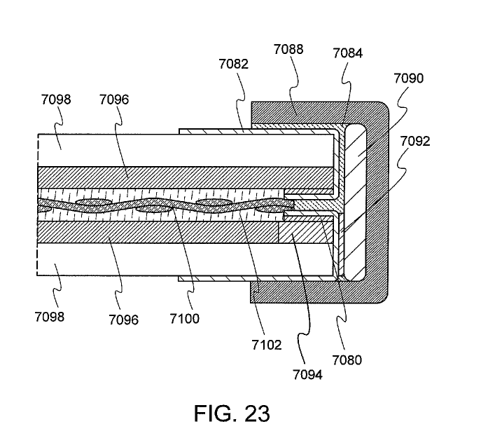

FIG. 23 illustrates a structure in which a power storage device 7090 is provided inside the frame 7088 of a photoelectric conversion device. A terminal 7092 of the power storage device 7090 is provided so as to be in contact with at least one of the wiring members 7082. In that case, a backflow prevention diode 7094 formed using a semiconductor layer and a conductive film which are included in the cell 7096 is preferably formed between the cell 7096 and the power storage device 7090.

Note that as the power storage device 7090, a secondary battery such as a nickel-hydrogen battery or a lithium-ion battery, a capacitor such as a lithium-ion capacitor, or the like can be used. A secondary battery or a capacitor utilizing sodium instead of lithium may be used as an electrode material in such a power storage unit. When the power storage device 7090 is formed in a film form, reductions in thickness and weight can be achieved. The frame 7088 can also function as a reinforcement member of the power storage device 7090.

Note that this embodiment can be combined with any of the other embodiments as appropriate.

### Embodiment 14

In this embodiment, improvement in photoelectric conversion efficiency by a plurality of photoelectric conversion layers was confirmed. Specifically, the dependence of photoelectric conversion efficiency (quantum efficiency) of a photoelectric conversion layer using amorphous silicon and a photoelectric conversion layer using single crystal silicon on wavelengths was obtained by computer calculation. The device simulator Atlas manufactured by Silvaco, Inc. was used as calculation software.

The photoelectric conversion layer used for the calculation had a p-i-n junction structure. As for the photoelectric conversion layer using amorphous silicon, the thicknesses of a p layer, an i layer, and an n layer were 10 nm, 200 nm, and 10 nm, respectively. As for the photoelectric conversion layer using single crystal silicon, the thicknesses of a p layer, an i layer, and an n layer were 10 nm, 30 μm, and 10 nm, respectively. Note that the concentrations of impurity elements in the p layer and the n layer were both 1×10¹⁹ (cm⁻³), and the calculation was performed under the condition where all the impurity elements were activated. In addition, reflection, scattering, absorption, and the like of light at a conductive layer serving as an electrode or an intermediate layer or at an interface between the conductive layer and the photoelectric conversion layer were not considered.

In this embodiment, for simplicity, the quantum efficiency of each photoelectric conversion layer was individually calculated under the condition where the amount of light which enters the photoelectric conversion layer using amorphous silicon and the amount of light which enters the photoelectric conversion layer using single crystal silicon are the same.

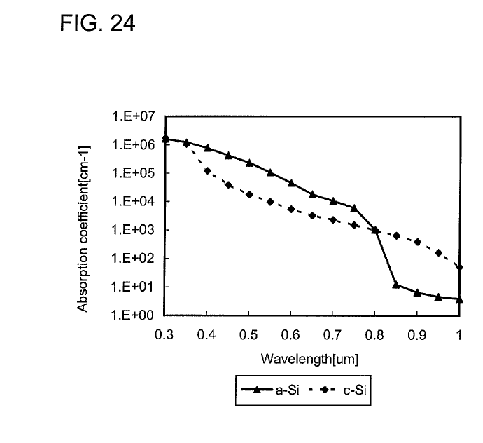

FIG. 24 shows the light absorption coefficients (cm⁻¹) of amorphous silicon (a-Si) and single crystal silicon (c-Si) which were used as the precondition of the calculation. In FIG. 24, the horizontal axis represents wavelength (μm) and the vertical axis represents absorption coefficient (cm⁻¹) with respect to corresponding wavelengths.

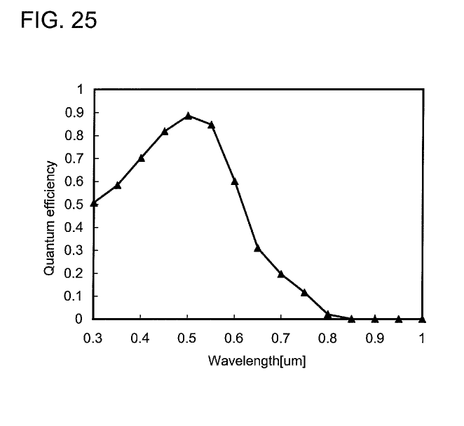

FIG. 25 shows the quantum efficiency of the photoelectric conversion layer using amorphous silicon (a-Si), which was calculated on the basis of the above data. In FIG. 25, the horizontal axis represents wavelength (μm) and the vertical axis represents quantum efficiency with respect to corresponding wavelengths. The quantum efficiency is obtained on the basis of a fraction in which the denominator is a current of the case where all incident light is converted into current and the numerator is a current of a negative electrode.

According to FIG. 25, the photoelectric conversion efficiency of the photoelectric conversion layer using amorphous silicon is high on the shorter wavelength side (0.4 μm to 0.6 μm). The photoelectric conversion layer using amorphous silicon is capable of sufficient photoelectric conversion even when the thickness is approximately 100 nm. Further, the photoelectric conversion layer using amorphous silicon is preferably used as a top cell because it can sufficiently transmit light with a longer wavelength.

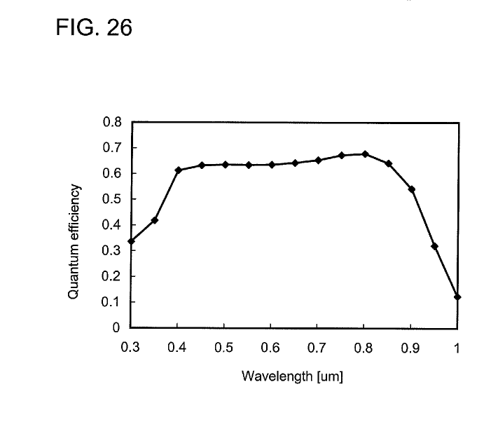

FIG. 26 shows the quantum efficiency of the photoelectric conversion layer using single crystal silicon (c-Si). In FIG. 26, as in FIG. 25, the horizontal axis represents wavelength (μm) and the vertical axis represents quantum efficiency with respect to corresponding wavelengths.

According to FIG. 26, the photoelectric conversion efficiency of the photoelectric conversion layer using single crystal silicon is high in a wide wavelength range (0.4 μm to 0.9 μm). The photoelectric conversion layer using single crystal silicon is preferably used as a bottom cell because its preferable thickness is several tens of micrometers.

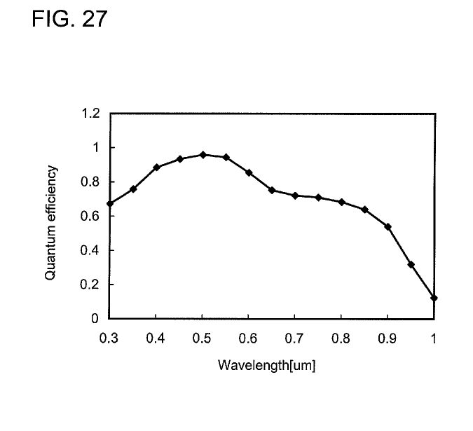

FIG. 27 shows the quantum efficiency of a structure in which the photoelectric conversion layer using amorphous silicon and the photoelectric conversion layer using single crystal silicon are stacked, which was obtained using the results shown in FIG. 25 and FIG. 26. Note that FIG. 27 shows the quantum efficiency of the case where the photoelectric conversion layer using amorphous silicon was used as a top cell and the photoelectric conversion layer using single crystal silicon was used as a bottom cell. Here, for simplicity, the calculation was performed with factors other than the above photoelectric conversion layers left out of consideration. In other words, an effect of an intermediate layer connecting the top cell and the bottom cell, or the like is not considered.

According to the calculation results of this embodiment, the wavelength suitable for the photoelectric conversion layer using amorphous silicon and the wavelength suitable for the photoelectric conversion layer using single crystal silicon were different. In other words, it can be said that the photoelectric conversion efficiency can be improved when those photoelectric conversion layers are stacked.

Note that this embodiment can be combined with any of the other embodiments as appropriate.

This application is based on Japanese Patent Application serial no. 2009-136672 filed with Japan Patent Office on Jun. 5, 2009, the entire contents of which are hereby incorporated by reference.

1. A photoelectric conversion device comprising:
a first cell having a photoelectric conversion function;
a structure body over the first cell, the structure body including a fibrous body and a resin; and
a second cell having a photoelectric conversion function over the structure body;
wherein the first cell and the second cell adhere to each other with the structure body.

2. The photoelectric conversion device according to claim 1, wherein each of the first cell and the second cell includes a photoelectric conversion layer interposed between a first conductive film and a second conductive film.

3. The photoelectric conversion device according to claim 1, wherein each of the first cell and the second cell includes a photoelectric conversion layer interposed between a first conductive film and a second conductive film, and wherein the photoelectric conversion layer includes a p-type semiconductor layer and an n-type semiconductor layer.

4. The photoelectric conversion device according to claim 1, wherein each of the first cell and the second cell includes at least a photoelectric conversion layer interposed between a first conductive film and a second conductive film, and wherein the photoelectric conversion layer includes a p-type semiconductor layer, an i-type semiconductor layer, and an n-type semiconductor layer.

5. The photoelectric conversion device according to claim 1, wherein each of the first cell and the second cell includes at least one of amorphous silicon, crystalline silicon, and single crystal silicon.

6. The photoelectric conversion device according to claim 1, wherein the fibrous body is impregnated with the resin.

7. The photoelectric conversion device according to claim 1, wherein the fibrous body is impregnated with the resin, and wherein the resin is an organic resin.

8. A photoelectric conversion device comprising:
a first substrate;
a first cell having a photoelectric conversion function over the first substrate;
a structure body over the first cell, the structure body including a fibrous body and a resin;
a second cell having a photoelectric conversion function over the structure body; and
a second substrate over the second cell,
wherein the first cell and the second cell adhere to each other with the structure body.

9. The photoelectric conversion device according to claim 8, wherein each of the first cell and the second cell includes a photoelectric conversion layer interposed between a first conductive film and a second conductive film.

10. The photoelectric conversion device according to claim 8, wherein each of the first cell and the second cell includes a photoelectric conversion layer interposed between a first conductive film and a second conductive film, and wherein the photoelectric conversion layer includes a p-type semiconductor layer and an n-type semiconductor layer.

11. The photoelectric conversion device according to claim 8, wherein each of the first cell and the second cell includes at least a photoelectric conversion layer interposed between a first conductive film and a second conductive film, and wherein the photoelectric conversion layer includes a p-type semiconductor layer, an i-type semiconductor layer, and an n-type semiconductor layer.

12. The photoelectric conversion device according to claim 8, wherein each of the first cell and the second cell includes at least one of amorphous silicon, crystalline silicon, and single crystal silicon.

13. The photoelectric conversion device according to claim 8, wherein the fibrous body is impregnated with the resin.

14. The photoelectric conversion device according to claim 8, wherein the fibrous body is impregnated with the resin, and wherein the resin is an organic resin.

15. A method for manufacturing a photoelectric conversion device, comprising the steps of:
forming a first cell having a photoelectric conversion function;
forming a second cell having a photoelectric conversion function;
making the first cell adhere to a structure body including a fibrous body and a resin; and
making the second cell adhere to the structure body.

16. The method for manufacturing a photoelectric conversion device, according to claim 15, wherein a first conductive film, a photoelectric conversion layer, and a second conductive film is formed as each of the first cell and the second cell.

17. The method for manufacturing a photoelectric conversion device, according to claim 15, wherein a first conductive film, a p-type semiconductor layer, an n-type semiconductor layer, and a second conductive film are formed as each of the first cell and the second cell.

18. The method for manufacturing a photoelectric conversion device, according to claim 15, wherein a first conductive film, a p-type semiconductor layer, an i-type semiconductor layer, an n-type semiconductor layer, and a second conductive film are formed as each of the first cell and the second cell.
